(19) United States
(12) Patent Application Publication
(10) Pub. No.: US 2026/0090168 A1
(43) Pub. Date: Mar. 26, 2026

(54) DISPLAY DEVICE

(71) Applicant: Samsung Display Co., Ltd., Yongin-si (KR)

(72) Inventors: Jong Moo HUH, Yongin-si (KR); Kyung Rock SON, Yongin-si (KR); Jae Phil LEE, Yongin-si (KR)

(21) Appl. No.: 19/291,824

(22) Filed: Aug. 6, 2025

(30) Foreign Application Priority Data
Sep. 20, 2024 (KR) 10-2024-0127378

(51) Int. Cl. H10H 29/49

(52) U.S. Cl. CPC H10H 29/49

(57) ABSTRACT

A display device includes a substrate, a pixel electrode above the substrate, a first type light-emitting element above the pixel electrode, and having a contact electrode electrically connected to the pixel electrode, a second type light-emitting element above the pixel electrode, and having a non-contact electrode, a filling layer between the first type light-emitting element and the second type light-emitting element, a connect electrode connecting the first type light-emitting element and the second type light-emitting element in series, and a common electrode above the first type light-emitting element and the second type light-emitting element, and electrically connected to the second type light-emitting element.

### CROSS-REFERENCE TO RELATED APPLICATION

The present application claims priority to, and the benefit of, Korean Patent Application No. 10-2024-0127378, filed on Sep. 20, 2024, in the Korean Intellectual Property Office, the entire disclosure of which is incorporated herein by reference.

### BACKGROUND

### 1. Field

The present disclosure relates to a display device.

### 2. Description of the Related Art

With the development of the information society, the demand for display devices for displaying images is increasing in various forms. The display device may be a flat panel display such as a liquid crystal display, a field emission display, a light-emitting display, and the like.

The light-emitting display device may be implemented as an organic light-emitting display device including an organic light-emitting diode (OLED) element as the light-emitting element, an inorganic light-emitting display device including an inorganic semiconductor element as the light-emitting element, or an ultra-small light-emitting diode display device including an ultra-small light-emitting diode element (or micro light-emitting diode element) as the light-emitting element.

### SUMMARY

Aspects of embodiments of the present disclosure provide a display device capable of reducing power consumption by connecting light-emitting elements in series.

In addition, aspects of embodiments of the present disclosure provide a display device capable of securing a sufficient width of the active layer of light-emitting elements connected in series, and reducing or minimizing the number of processes.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate, a pixel electrode above the substrate, a first type light-emitting element above the pixel electrode, and having a contact electrode electrically connected to the pixel electrode, a second type light-emitting element above the pixel electrode, and having a non-contact electrode, a filling layer between the first type light-emitting element and the second type light-emitting element, a connect electrode connecting the first type light-emitting element and the second type light-emitting element in series, and a common electrode above the first type light-emitting element and the second type light-emitting element, and electrically connected to the second type light-emitting element.

The first type light-emitting element and the second type light-emitting element may include a first semiconductor layer, an active layer, and a second semiconductor layer, wherein the second semiconductor layer of the first type light-emitting element includes a first portion having a first thickness, and a second portion having a second thickness that is less than the first thickness, and wherein the active layer and the first semiconductor layer of the first type light-emitting element overlap the first portion.

The first type light-emitting element may further include a protective layer surrounding, in plan view, side surfaces of the first semiconductor layer, the active layer, and the second semiconductor layer of the first type light-emitting element, defining a first opening exposing the first semiconductor layer of the first type light-emitting element, and defining a second opening exposing the second semiconductor layer of the first type light-emitting element at the second portion, wherein the second type light-emitting element further includes a protective layer surrounding side surfaces, in plan view, of the first semiconductor layer, the active layer, and the second semiconductor layer of the second type light-emitting element, and defining a third opening exposing the first semiconductor layer of the second type light-emitting element.

The contact electrode may be electrically connected to the first semiconductor layer through the first opening, wherein the connect electrode connects the second semiconductor layer of the first type light-emitting element with the first semiconductor layer of the second type light-emitting element through the second opening and the third opening.

The non-contact electrode may be on the protective layer on one surface of the second type light-emitting element.

The display device may further include an organic layer defining a fourth opening covering the first type light-emitting element and exposing the second semiconductor layer of the second type light-emitting element.

The common electrode may be electrically connected to the second semiconductor layer of the second type light-emitting element through the fourth opening, and overlaps, while being separated from, the first type light-emitting element in a thickness direction.

A width of the active layer of the first type light-emitting element may be substantially equal to a width of the active layer of the second type light-emitting element.

The contact electrode and the non-contact electrode may be at a same height.

The filling layer may include an insulating material, wherein a surface of the filling layer includes a light-reflecting surface or a light-absorbing surface.

The first type light-emitting element and the second type light-emitting element may include a reflective layer surrounding, in plan view, at least a portion of a side surface thereof.

Upper portions of the first type light-emitting element and the second type light-emitting element may include a concave light extraction pattern having a hemisphere or a semi-ellipse shape.

The common electrode may contact the concave light extraction pattern of the second type light-emitting element.

According to an aspect of the present disclosure, a display device includes a substrate, a first pixel electrode and a second pixel electrode spaced apart from each other, and above the substrate, a first type light-emitting element having a contact electrode above the first pixel electrode, and electrically connected to the first pixel electrode, a bonding electrode between the first pixel electrode and the contact electrode, a second type light-emitting element on the second pixel electrode, a filling layer between the first type light-emitting element and the second type light-emitting element, a connect electrode connecting the first type light-emitting element and the second type light-emitting element in series, and a common electrode above the first type light-emitting element and the second type light-emitting element, and electrically connected to the second type light-emitting element, wherein a height of the second pixel electrode is substantially equal to a sum of a height of the first pixel electrode, a height of the bonding electrode, and a height of the contact electrode.

The first type light-emitting element and the second type light-emitting element may include a first semiconductor layer, an active layer, and a second semiconductor layer, wherein the second semiconductor layer of the first type light-emitting element includes a first portion having a first thickness, and a second portion having a second thickness that is less than the first thickness, and wherein the active layer and the first semiconductor layer of the first type light-emitting element overlap the first portion.

The contact electrode may be electrically connected to the first semiconductor layer of the first type light-emitting element, wherein the connect electrode connects the second semiconductor layer of the second portion of the first type light-emitting element with the first semiconductor layer of the second type light-emitting element.

The display device may further include an organic layer covering both the first type light-emitting element and the second type light-emitting element, and having an opening exposing the second semiconductor layer of the second type light-emitting element, wherein the common electrode is electrically connected to the second semiconductor layer of the second type light-emitting element, overlaps the first type light-emitting element in a thickness direction, and is separated from the first type light-emitting element.

A width of the active layer of the first type light-emitting element may be substantially equal to a width of the active layer of the second type light-emitting element.

The filling layer may include an insulating material, and has a light-reflecting surface or a light-absorbing surface.

According to an aspect of the present disclosure, an electronic device includes a display device including a substrate, a pixel electrode above the substrate, a first type light-emitting element above the pixel electrode, and having a contact electrode electrically connected to the pixel electrode, a second type light-emitting element above the pixel electrode, and having a non-contact electrode, a filling layer between the first type light-emitting element and the second type light-emitting element, a connect electrode connecting the first type light-emitting element and the second type light-emitting element in series, and a common electrode above the first type light-emitting element and the second type light-emitting element, and electrically connected to the second type light-emitting element.

According to the display device and its manufacturing method according to the embodiments, power consumption may be reduced by connecting light-emitting elements in series.

In addition, the width of the active layer of light-emitting elements connected in series may be secured sufficiently, and the number of processes may be reduced or minimized.

However, the present disclosure is not limited to the aforementioned effects, and various other aspects are included in the present specification.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is a layout diagram illustrating pixels of a display area according to one or more embodiments.

FIG. 6 is a cross-sectional view illustrating an example cross-section of one display panel taken along the line I-I′ in FIG. 5.

FIG. 7 is a cross-sectional view illustrating an example of area A in FIG. 6 in detail.

FIG. 8 is a cross-sectional view illustrating another example of area A in FIG. 7 in detail.

FIG. 9 is a cross-sectional view illustrating an example of area A of FIG. 6 according to one or more other embodiments in detail.

FIG. 10 is a cross-sectional view illustrating an example of area A of FIG. 6 according to one or more other embodiments in detail.

FIG. 11 is a cross-sectional view illustrating an example of area A of FIG. 6 according to one or more other embodiments in detail.

FIG. 12 is a flowchart illustrating a method of manufacturing a display device according to one or more embodiments.

FIGS. 13 to 25 are drawings to illustrate a method of manufacturing a display device according to one or more embodiments.

FIG. 26 is a view of a smart watch including a display device according to one or more embodiments;

FIGS. 27 and 28 are views of a virtual reality (VR) device including a display device according to one or more embodiments;

FIG. 29 is a view of a VR device including a display device according to one or more embodiments;

FIG. 30 is a view illustrating a vehicle instrument cluster and center fascia including display devices according to one or more embodiments; and

FIG. 31 is a view of a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),”“second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

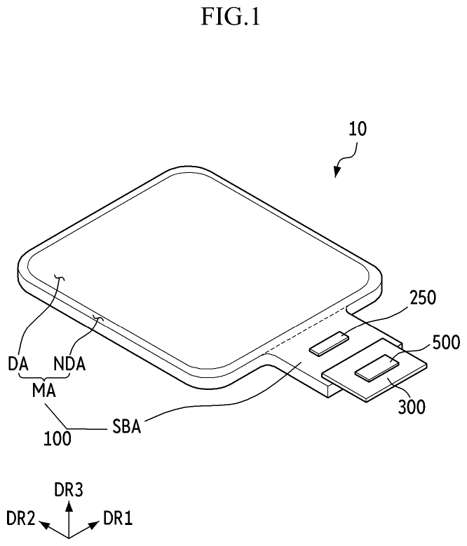

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices, such as smart watches, watch phones, mobile communication terminals, electronic notebooks, e-books, portable electronic devices, such as portable multimedia players (PMP), navigation, and ultra mobile PCs (UMPC), as well as display screens for a variety of products, such as televisions, laptops, monitors, billboards, and the internet of things (IOT).

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description mainly describes the display device 10 as a micro-light-emitting display device, but the present disclosure is not limited thereto. On the other hand, the subminiature light-emitting diode is described herein as a micro light-emitting element for convenience of explanation.

The display device 10 includes a display panel 100, a display-driving circuit 250, a circuit board 300, and a power supply circuit 500.

The display panel 100 may be formed as a rectangular-shaped plane having a short side in the first direction DR1, and a long side in the second direction DR2 that crosses the first direction DR1. A corner where the short side in the first direction DR1 and the long side in the second direction DR2 meet may be rounded to have a corresponding curvature or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be flexible, such as to be able to be bent, curved, bent, folded, or rolled.

The substrate SUB of the display panel 100 may include a main area MA and a sub-area SBA.

The main area MA may include a display area DA that displays an image, and a non-display area NDA that is a peripheral area of the display area .DA. The display area DA may include a plurality of pixels that display an image. Each pixel may include a plurality of sub-pixels. For example, each of the pixels may include a first sub-pixel that emits light of a first color, a second sub-pixel that emits light of a second color, and a third sub-pixel that emits light of a third color. However, the embodiments of the present disclosure are not limited thereto.

The sub-area SBA may protrude from one side of the main area MA in the second direction DR2. Although FIG. 1 illustrates the sub-area SBA being unfolded, the sub-area SBA may be bent, and in this case, may be located on the bottom surface of the display panel 100. When the sub-area SBA is bent, it may overlap the main area MA in the third direction DR3, which is the thickness direction of the display panel 100. The display-driving circuit 250 may be located in the sub-area SBA.

The display-driving circuit 250 may generate signals and voltages for driving the display panel 100. The display-driving circuit 250 may be formed as an integrated circuit (IC), and may be attached to the display panel 100 using a chip-on-glass (COG) method, a chip-on-plastic (COP) method, or an ultrasonic bonding method but is not limited thereto. For example, the display-driving circuit 250 may be attached to the circuit board 300 using a chip-on-film (COF) method.

The circuit board 300 may be attached to one end of the sub-area SBA of the display panel 100. As such, the circuit board 300 may be electrically connected to the display panel 100 and the display-driving circuit 250. The display panel 100 and the display-driving circuit 250 may receive digital video data, timing signals, and driving voltages through the circuit board 300. The circuit board 300 may be a flexible film, such as a flexible printed circuit board, a printed circuit board, or a chip on film.

The power supply circuit 500 may generate a plurality of panel driving voltages according to an external power supply voltage. The power supply circuit 500 may be formed as an integrated circuit (IC) and attached to the circuit board 300 using a COF method.

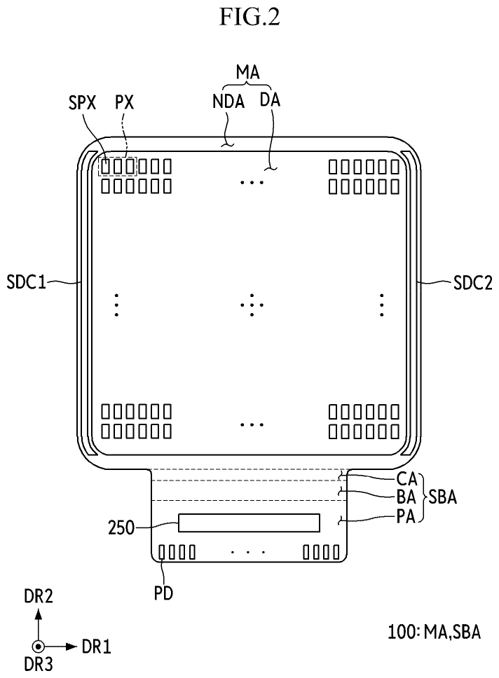

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image, and the non-display area NDA that is a peripheral area of the display area DA. The display area DA may occupy most of the main area MA. The display area DA may be placed generally in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may surround the display area DA (e.g., in plan view). The non-display area NDA may be an edge area of the display panel 100.

A first scan driver SDC1 and a second scan driver SDC2 may be located in the non-display area NDA. The first scan driver SDC1 is located on one side (for example, the left side) of the display panel 100, and the second scan driver SDC2 is located on the other side (for example, the right side) of the display panel 100. However, the present disclosure is not limited thereto.

Each of the first scan driver SDC1 and the second scan driver SDC2 may be electrically connected to the display-driving circuit 250 through scan fan-out lines. Each of the first scan driver SDC1 and the second scan driver SDC2 may receive a scan control signal from the display-driving circuit 250, may generate scan signals according to the scan control signal, and may output them to the scan lines.

The sub-area SBA may protrude from one side of the main area MA in the second direction DR2. The length of the sub-area SBA in the second direction DR2 may be less than the length of the main area MA in the second direction DR2. The length of the first direction DR1 of the sub-area SBA is less than the length of the first direction DR1 of the main area MA, or may be substantially equal to the length of the first direction DR1 of the main area MA. The sub-area SBA may be curved, and may be located at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display-driving circuit 250 are located. The display-driving circuit 250 may be attached to the driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA is a bent area. When the bending area BA is bent, the pad area PA may be located below the connection area CA and below the main area MA. The bending area BA may be located between the connection area CA and the pad area PA. One side of the bending area BA may be in contact with the connection area CA, and the other side of the bending area BA may be in contact with the pad area PA.

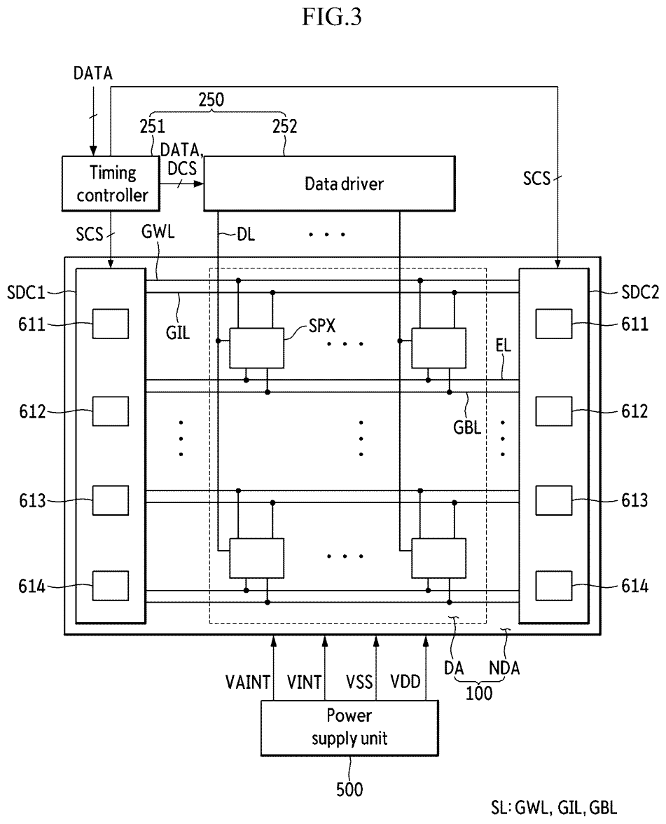

FIG. 3 is a block diagram illustrating a display device according to one or more embodiments.

Referring to FIG. 3, the display area DA includes a plurality of pixels PX, a plurality of scan lines, a plurality of emission control lines EL, and a plurality of data lines DL.

The plurality of pixels PX may be arranged in a matrix form in the first direction DR1 and the second direction DR2. The plurality of scan lines and the plurality of emission control lines EL may extend in the first direction DR1, and may be located in the second direction DR2. The plurality of data lines DL may extend in the second direction DR2, and may be located in the first direction DR1. The plurality of scan lines may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light-emitting elements according to the data voltage.

The non-display area NDA includes a first scan driver SDC1, a second scan driver SDC2, and a display-driving circuit 250.

Each of the first scan driver SDC1 and the second scan driver SDC2 may include a write scan signal output 611, a control scan signal output 612, an initialization scan signal output 613, a bias scan signal output 614, and a light emission signal output 615. The write scan signal output 611, control scan signal output 612, initialization scan signal output 613, bias scan signal output 614, and light emission signal output 615 may each receive a scan-timing control signal SCS from the timing control circuit 400. The write scan signal output 611 may generate write scan signals according to the scan-timing control signal SCS of the timing control circuit 400, and may sequentially output them to the write scan lines GWL. The control scan signal output 612 may generate control scan signals according to the scan-timing control signal SCS, and may sequentially output them to the control scan lines GCL. The initialization scan signal output 613 may generate initialization scan signals according to the scan-timing control signal SCS, and may sequentially output them to the initialization scan lines GIL. The bias scan signal output 614 may generate bias scan signals according to the scan-timing control signal SCS, and may sequentially output them to the bias scan lines EBL. The light emission signal output 615 may generate emission control signals according to the scan-timing control signal SCS, and may sequentially output them to the emission control lines EL.

The display-driving circuit 250 includes a timing control circuit 251 and a data driver 252.

The data driver 252 may receive digital video data DATA and a data-timing control signal DCS from the timing control circuit 251. The data driver 252 converts digital video data DATA into analog data voltages according to the data-timing control signal DCS, and outputs them to the data lines DL. In this case, the sub-pixels SPX are selected by the write scan signals of the first scan driver SDC1 and the second scan driver SDC2, and data voltages may be supplied to the selected sub-pixels SPX.

The timing control circuit 251 may receive digital video data and timing signals from an external source. The timing control circuit 251 may generate the scan-timing control signal SCS and the data-timing control signal DCS to control the display panel 100 according to timing signals. The timing control circuit 400 may output the scan-timing control signal SCS to the first scan driver SDC1 and the second scan driver SDC2. The timing control circuit 251 may output digital video data DATA and a data-timing control signal DCS to the data driver 252.

The power supply circuit 500 may generate a plurality of panel driving voltages according to an external power supply voltage. For example, the power supply circuit 500 may generate and supply a first driving voltage VDD, a second driving voltage VSS, and a third driving voltage VINT.

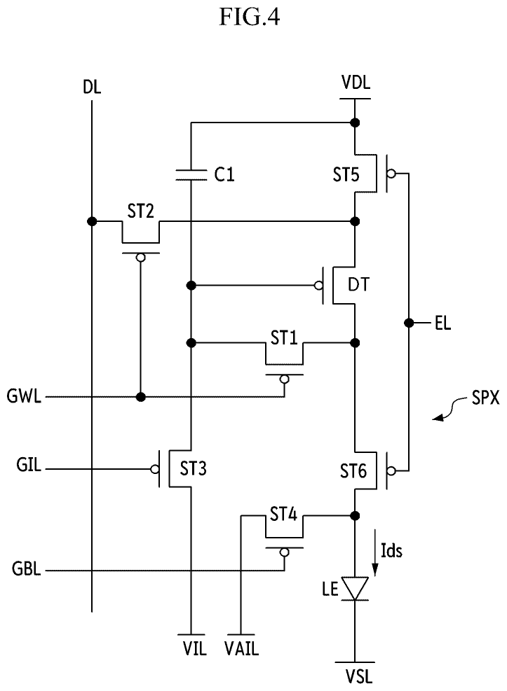

FIG. 4 is an equivalent circuit diagram illustrating a sub-pixel according to one or more embodiments.

Referring to FIG. 4, a sub-pixel SPX according to one or more embodiments may be connected to scan lines GWL, GIL, GCL, and GBL, an emission line EL, and a data line DL. For example, the sub-pixel SPX may be connected to a write scan line GWL, an initialization scan line GIL, a control scan line GCL, a bias scan line GBL, an emission line EL, and a data line DL.

The sub-pixel SPX1 according to one or more embodiments includes a driving transistor DT, switch elements, a capacitor C1, and a light-emitting element LE. The switch elements include first to sixth transistors ST1, ST2, ST3, ST4, ST5, and ST6.

The driving transistor DT includes a gate electrode, a conductive layer, and a second electrode. The driving transistor DT controls the drain-source current (Ids, hereinafter referred to as “driving current”) flowing between the conductive layer and the second electrode according to the data voltage applied to the gate electrode.

The light-emitting element LE may be a micro light-emitting diode. The light-emitting element LE emits light according to the driving current Ids. The anode electrode of the light-emitting element LE is connected to the conductive layer of the fourth transistor ST4 and the second electrode of the sixth transistor ST6, and the cathode electrode may be connected to a second power supply line VSL to which the second power supply voltage is applied.

The capacitor C1 is formed between the second electrode of the driving transistor DT and the first power supply line VDL to which the first power supply voltage is applied. The first power supply voltage may be at a higher level than the second power supply voltage. One electrode of the capacitor C1 may be connected to the second electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type metal-oxide-semiconductor field-effect transistor (MOSFET). In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, the gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, the control scan line GCL, the initialization scan line GIL, the write scan line GWL, the bias scan line GBL, and the light emission line EL may be turned on when a scan signal and a light-emitting signal of the gate low voltage are applied, respectively. One electrode of the third transistor ST3 and one electrode of the fourth transistor ST4 may be connected to the initialization voltage line VIL.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. The active layer of each of the driving transistor DT, the second transistor ST2, the fourth transistor ST4, the fifth transistor ST5, and the sixth transistor ST6 formed of a p-type MOSFET may be formed of polysilicon, and the active layer of each of the first and third transistors ST1 and ST3 formed as an n-type MOSFET may be formed of an oxide semiconductor.

In this case, because the first transistor ST1 and the third transistor ST3 are formed as n-type MOSFET, the first transistor ST1 may be turned on when a scan signal of a gate high voltage is applied, and the third transistor ST3 may be turned on when an initialization scan signal with the gate high voltage is applied. In comparison, the second transistor ST2, the fourth transistor ST4, the fifth transistor ST5, and the sixth transistor ST6 are formed as p-type MOSFET, so that they may be turned on when a scan signal of the gate low voltage and a light emission control signal are applied.

Alternatively, the fourth transistor ST4 may be formed of an n-type MOSFET, so that each active layer of the fourth transistor ST4 may be formed of an oxide semiconductor. When the fourth transistor ST4 is formed of an n-type MOSFET, it may be turned on when a scan signal of the gate high voltage is applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT may be formed of an oxide semiconductor.

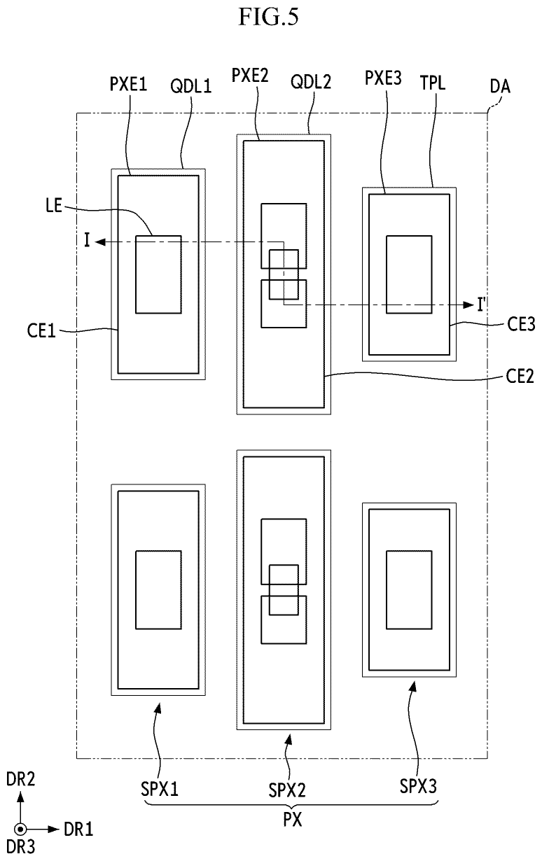

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the present disclosure is not limited thereto and may include four sub-pixels. When each of the plurality of pixels PX includes three sub-pixels SPX1, SPX2, and SPX3, the first sub-pixel SPX1, the second sub-pixel SPX2, and the third sub-pixel SPX3 may include.

The plurality of pixels PX may be located in a matrix form. In each of the plurality of pixels PX, the first sub-pixel SPX1, the second sub-pixel SPX2, and the third sub-pixel SPX3 may be arranged in a first direction DR1.

When each of the plurality of pixels PX includes three sub-pixels SPX1, SPX2, and SPX3, the first sub-pixel SPX1 may emit light of a first color, the second sub-pixel SPX2 may emit light of a second color, and the third sub-pixel SPX3 may emit light of a third color. Here, the light of the first color may be light in the green wavelength band, the light of the second color may be light in the red wavelength band, and the light of the third color may be light in the blue wavelength band. For example, the blue wavelength band may refer to light having a main peak wavelength in the wavelength band from approximately 370 nm to approximately 460 nm, the green wavelength band may refer to light having a main peak wavelength in the wavelength band from approximately 480 nm to approximately 560 nm, and the red wavelength band may refer to light having a main peak wavelength in the wavelength band from approximately 600 nm to approximately 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, one or more light-emitting elements LE, and a first light conversion layer QDL1. The second sub-pixel SPX2 includes a second pixel electrode PXE2 one or more light-emitting elements LE, and a second light conversion layer QDL2. The third sub-pixel SPX3 includes a third pixel electrode PXE3, one or more light-emitting elements LE, and a transmission layer TPL.

Each of the first pixel electrode PXE1, the second pixel electrode PXE2, and the third pixel electrode PXE3 may have a rectangular planar shape having a short side in the first direction DR1 and a long side in the second direction DR2. The area of the first sub-pixel SPX1, the area of the second sub-pixel SPX2, and the area of the third sub-pixel SPX3 may be set according to the light conversion efficiency of the first light conversion layer QDL1 and the light conversion efficiency of the second light conversion layer QDL2. For example, the area of the sub-pixel may become larger as the light conversion efficiency decreases.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, because the light transmission layer TPL directly transmits the light of the light-emitting element LE, while the first light conversion layer QDL1 need to convert the light, the area of the first pixel electrode PXE1 may be larger than the area of the third pixel electrode PXE3.

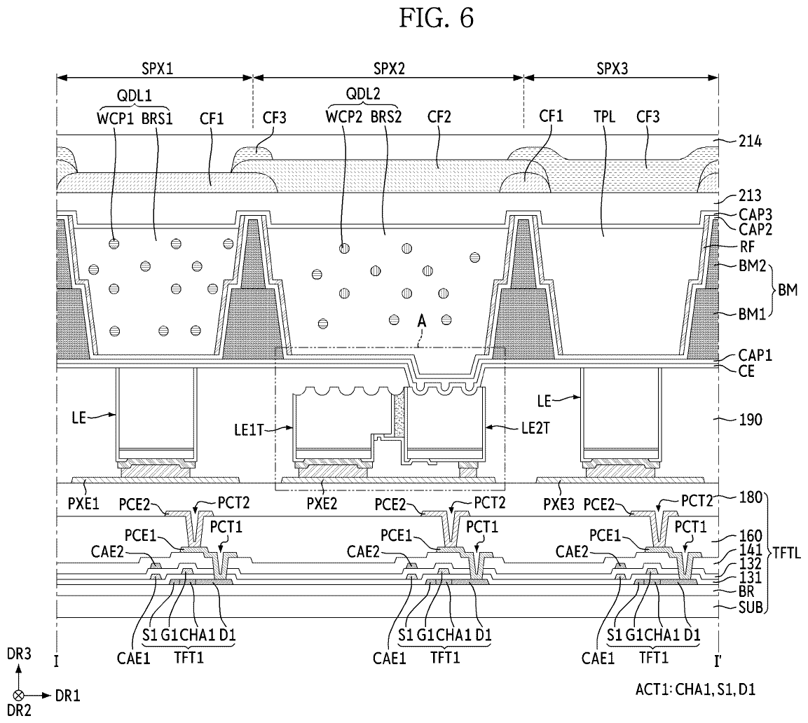

When the light conversion efficiency of the second light conversion layer QDL2 is lower than the light conversion efficiency of the first light conversion layer QDL1, the number of light-emitting elements located on the second pixel electrode PXE2 may be greater than the number of light-emitting elements located on the first pixel electrode PXE1. For example, and referring to FIG. 6, one light-emitting element may be located on a first pixel electrode PXE1, and two light-emitting elements, a first type light-emitting element LE1T and a second type light-emitting element LE2T, may be located on a second pixel electrode PXE2. The first type light-emitting element LE1T and the second type light-emitting element LE2T may be connected in series. The present disclosure is not limited thereto. For example, the first type light-emitting element LE1T and the second type light-emitting element LE2T may be located on each of the pixel electrodes PXE1, PXE2, and PXE3 in series.

Each of the plurality of light-emitting elements LE may have a rectangular planar shape, but the embodiments of the present disclosure are not limited thereto. For example, each of the plurality of light-emitting elements LE may have a circular planar shape.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and to the second electrode of the sixth transistor (ST6 in FIG. 4) of the corresponding sub-pixel.

The first light conversion layer QDL1 may completely overlap the first pixel electrode PXE1 and the plurality of light-emitting elements LE of the first sub-pixel SPX1. The area of the first light conversion layer QDL1 may be larger than the area of the first pixel electrode PXE1. The first light conversion layer QDL1 may convert or shift the peak wavelength of incident light into light of another corresponding peak wavelength and emit it. For example, the first light conversion layer QDL1 may convert or shift the third light emitted from the plurality of light-emitting elements LE of the first sub-pixel SPX1 into first light.

The second light conversion layer QDL2 may completely overlap the plurality of light-emitting elements LE of the second pixel electrode PXE2 and the second sub-pixel SPX2. The area of the second light conversion layer QDL2 may be larger than the sum of the areas of the second pixel electrode PXE2 and the second common electrode CE2. The second light conversion layer QDL2 may convert or shift the peak wavelength of incident light into light of another corresponding peak wavelength to emit it. For example, the second light conversion layer QDL2 may convert or shift the third light emitted from the plurality of light-emitting elements LE of the second sub-pixel SPX2 into second light.

The light transmission layer TPL may completely overlap the plurality of light-emitting elements LE of the third pixel electrode PXE3 and the third sub-pixel SPX3. The area of the light transmission layer TPL may be larger than the sum of the areas of the third pixel electrode PXE3 and the third common electrode CE3. For example, the light transmission layer TPL may directly transmit the third light emitted from the plurality of light-emitting elements LE of the third sub-pixel SPX3.

When the light-emitting element LE of the first sub-pixel SPX1 emits light of the first color, the light-emitting element LE of the second sub-pixel SPX2 emits light of the second color, and the light-emitting element LE of the third sub-pixel SPX3 emits light of the third color, the light conversion layers QDL1 and QDL2 and the light transmission layer TPL may be omitted.

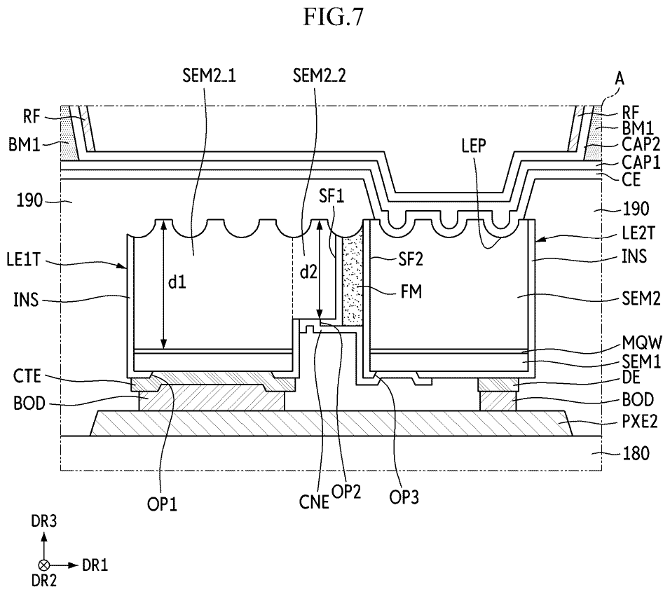

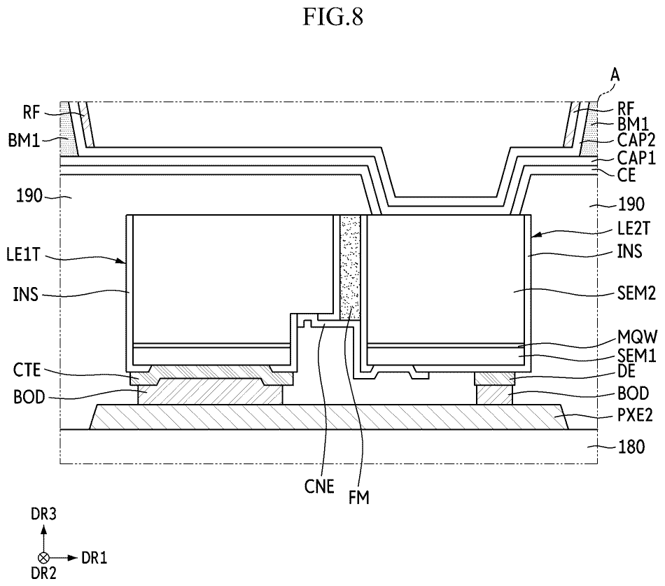

FIG. 6 is a cross-sectional view illustrating an example cross-section of one display panel taken along the line I-I′ in FIG. 5. FIG. 7 is a cross-sectional view illustrating an example of area A in FIG. 6 in detail. FIG. 8 is a cross-sectional view illustrating another example of area A in FIG. 7 in detail.

Referring to FIGS. 6 and 7, a substrate SUB may be made of an insulating material, such as glass, polymer resin, or the like. If the substrate SUB is made of polymer resin, it may be a flexible substrate that may be stretched. The polymer resin may be acrylic resin, epoxy resin, phenolic resin, polyamide resin, polyimide resin, or the like.

A barrier film BR may be located on the substrate SUB (as used herein, “located on” may mean “above”). The barrier film BR is a film that protects the transistors of the thin film transistor layer TFTL and the light-emitting layer 172 of the light-emitting element layer EML from moisture penetrating through the substrate SUB, which is vulnerable to moisture penetration. The barrier film BR may be composed of a plurality of inorganic films stacked alternately.

A thin film transistor TFT1 may be located on the barrier film BR. The thin film transistor TFT1 may be, for example, either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be located on the barrier film BR. The first active layer ACT1 of the thin film transistor TFT1 may include polycrystalline silicon, monocrystalline silicon, low-temperature polycrystalline silicon, or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and/or oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be located on one side of the first channel area CHA1, and the first drain area D1 may be located on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate-insulating film 131 may be located on the first channel area CHA1, the first source area S1, and the first drain area D1 of the thin film transistor TFT1.

A first gate metal layer may be located on a first gate-insulating film 131. The first gate metal layer may include the first gate electrode G1 and the first capacitor electrode CAE1 of the thin film transistor TFT1. The first gate electrode G1 may overlap the first active layer ACT1 in the third direction DR3. In FIG. 6, the first gate electrode G1 and the first capacitor electrode CAE1 are shown to be located apart from each other, but the first gate electrode G1 and the first capacitor electrode CAE1 may be connected to each other.

A second gate-insulating film 132 may be located on the first gate electrode G1 and the first capacitor electrode CAE1 of the thin film transistor TFT1.

A second gate metal layer may be located on the second gate-insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate-insulating film 132 has a dielectric constant (e.g., predetermined dielectric constant), the capacitor (C1 in FIG. 4) may be formed by the first capacitor electrode CAE1, the second capacitor electrode CAE2, and the second gate-insulating film 132 located between them.

A first interlayer insulating film 141 may be located on the second capacitor electrode CAE2.

A first data metal layer may be located on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate-insulating film 131, the second gate-insulating film 132, and the interlayer insulating film 141.

A first planarization organic film 160 may be located on the first source connection electrode PCE1 to planarize a step caused by the thin film transistor TFT1.

A second data metal layer may be located on the first planarization organic film 160. The second data metal layer may include a second source connection electrode PCE2. The second source connection electrode PCE2 may be connected to the first source connection electrode PCE1 through a second source contact hole PCT2 penetrating the first planarization organic film 160.

A second planarization organic film 180 may be located on the second source connection electrode PCE2.

The barrier film BR, the first gate-insulating film 131, the second gate-insulating film 132, the third gate-insulating film 133, and the interlayer insulating film 141 may be formed from an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), or copper (Cu), or an alloy thereof.

The first planarization organic film 160 and the second planarization organic film 180 may be formed of an organic film, such as an acrylic resin, an epoxy resin, a phenolic resin, a polyamide resin, a polyimide resin, or the like.

A light-emitting element layer may be located on the second planarization organic film 180. The light-emitting element layer may include pixel electrodes PXE1, PXE2, PXE3, light-emitting elements LE, a common electrode CE, and an organic layer 190.

A pixel electrode layer may be located on the second planarization organic film 180. The pixel electrode layer may include a first pixel electrode PXE1, a second pixel electrode PXE2, and a third pixel electrode PXE3. Each of the pixel electrodes PXE1, PXE2, and PXE3 may be connected to the second source connection electrode PCE2 through a connection hole (CT1, CT2, and CT3 of FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The pixel electrode layer may be formed as a single layer or multiple layers of any one of molybdenum (Mo), aluminum (Al), chromium (Cr), gold (Au), titanium (Ti), nickel (Ni), neodymium (Nd), or copper (Cu), or alloys thereof. For example, the pixel electrode layer may be made of copper (Cu) with low sheet resistance to lower the resistance of each of the pixel electrodes PXE1, PXE2, and PXE3.

Each of the pixel electrodes PXE1, PXE2, and PXE3 may have one or more light-emitting elements located thereon.

One light-emitting element LE may be located on the first pixel electrode PXE1 and the third pixel electrode PXE3, and two light-emitting elements LE1T and LE2T may be located on the second pixel electrode PXE2. The light-emitting elements LE located on the first pixel electrode PXE1 and the third pixel electrode PXE3 may be referred to as third-type light-emitting elements LE to clearly distinguish them from the two light-emitting elements LE1T and LE2T located on the second pixel electrode PXE2. The first to third type light-emitting elements LE are illustrated as vertical type micro LED extending in the third direction DR3. A vertical micro LED refers to an LED having a structure in which a first semiconductor layer SEM1, an active layer MQW, and a second semiconductor layer SEM2 are sequentially arranged in a third direction DR3 that is vertical.

Each of the plurality of light-emitting elements LE1T, LE2T, and LE may be formed of an inorganic material, such as gallium nitride (GaN). Each of the plurality of light-emitting elements LE1T, LE2T, and LE may have a length in the first direction DR1, a length in the second direction DR2, and a length in the third direction DR3 of several to several hundred μm, respectively. For example, each of the plurality of light-emitting elements LE1T, LE2T, and LE may have a length in the first direction DR1, a length in the second direction DR2, and a length in the third direction DR3 of about 100 μm or less.

Each of the plurality of light-emitting elements LE1T, LE2T, and LE may be formed by growing on a semiconductor substrate, such as a silicon substrate or a sapphire substrate. The plurality of light-emitting elements LE1T, LE2T, LE may be transferred directly from the semiconductor substrate onto the pixel electrodes PXE1, PXE2, PXE3 of the display panel 100. Alternatively, the plurality of light-emitting elements LE1T, LE2T, LE may be transferred onto the pixel electrodes PXE1, PXE2, PXE3 of the display panel 100 by an electrostatic method using an electrostatic head or a stamp method using an elastic polymer material, such as PDMS or silicon as a transfer substrate.

Each of the plurality of light-emitting elements LE1T, LE2T, and LE may include a first semiconductor layer SEM1, an active layer MQW, and a second semiconductor layer SEM2 that are commonly and sequentially located. Further, each of the plurality of light-emitting elements LE1T, LE2T, and LE may further include a protective layer INS. The protective layer INS is a film for protecting an outer side of the plurality of light-emitting elements LE1T, LE2T, and LE, and the protective layer INS may surround the first semiconductor layer SEM1, the active layer MQW, and the second semiconductor layer SEM2. For example, the protective layer INS may be located on one surface and a side surface of the first semiconductor layer SEM1, the active layer MQW, and the second semiconductor layer SEM2.

The first type light-emitting element LE1 and the third type light-emitting element LE3 may further include a contact electrode CTE. The contact electrode CTE is located on one surface of the light-emitting element, and may be located, for example, on the lower surface of the first semiconductor layer SEM1. When a conductive layer is located on one surface of the first semiconductor layer SEM1, the contact electrode CTE may be located on the conductive layer.

The contact electrode CTE may be connected to the first semiconductor layer SEM1 (or on the conductive layer) that is exposed and not covered by the protective layer INS.

The contact electrode CTE may include one of molybdenum (Mo), aluminum (Al), chromium (Cr), gold (Au), titanium (Ti), nickel (Ni), neodymium (Nd), or copper (Cu). For example, the plurality of contact electrodes CTE may be formed as a two-layer structure of chromium (Cr) and gold (Au), a three-layer structure of titanium (Ti), aluminum (Al), or titanium (Ti), or a three-layer structure of indium tin oxide (ITO), silver (Ag), and indium tin oxide (ITO) to increase reflectivity.

A bonding electrode BOD may be located between the contact electrode CTE and the pixel electrodes PXE1 and PXE2. The bonding electrode BOD may serve as a bonding metal for bonding pixel electrodes PXE1 and PXE2 and the plurality of light-emitting elements LE1T, LE2T, and LE in the manufacturing process. For example, the bonding electrode BOD may include at least one of gold (Au), copper (Cu), tin (Sn), silver (Ag), aluminum (Al), or titanium (Ti). For example, the bonding electrode BOD may include, roughly, a 9:1 alloy, an 8:2 alloy, or a 7:3 alloy of gold and tin.

In one or more embodiments, a conductive layer may be further located on the first semiconductor layer SEM1. The conductive layer may be located on a portion of one surface of the first semiconductor layer SEM1. The conductive layer E1 may include any one of molybdenum (Mo), aluminum (Al), chromium (Cr), gold (Au), titanium (Ti), nickel (Ni), neodymium (Nd), or copper (Cu).

The first semiconductor layer SEM1 may include a semiconductor material layer doped with a first conductive dopant, such as magnesium (Mg), zinc (Zn), calcium (Ca), strontium (Sr), barium (Ba), or the like, for example gallium nitride (GaN).

The active layer MQW may be located on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but embodiments of the present disclosure are not limited thereto.

Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

For example, when the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light-emitting element LE that emits the third light (light in the blue wavelength band) may be approximately 10 wt % to 20 wt %.

The second semiconductor layer SEM2 may be located on the first semiconductor layer SEM1. The second semiconductor layer SEM2 may be a semiconductor material layer doped with a second conductivity type dopant, such as silicon (Si), germanium (Ge), tin (Sn), etc., for example, gallium nitride (GaN).

An electron-blocking layer may be located between the first semiconductor layer SEM1 and the active layer MQW. The electron-blocking layer may be a layer to suppress or prevent too many electrons from flowing into the active layer MQW. For example, the electron-blocking layer may be aluminum gallium nitride (AlGaN) or p-type aluminum gallium nitride (AlGaN) doped with p-type magnesium (Mg). The electron-blocking layer may be omitted.

A superlattice layer may be located between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

A light extraction pattern LEP may be formed on the top surface of the second semiconductor layer SEM2.

The light extraction patterns LEP may be patterns for increasing the efficiency of light emitted from the top surface of the light-emitting element LE. The light extraction patterns LEP may be concave patterns formed in a hemisphere or a semi-ellipse. The light extraction patterns LEP may be concave patterns having a cross-sectional shape of a semicircle or a semi-ellipse. A maximum length Lmax of the light extraction patterns LEP in the third direction DR3 may be approximately 100 nm. Further, the distance between adjacent light extraction patterns LEP may be approximately 100 nm or less.

The light extraction patterns LEP may be omitted as shown in FIG. 8.

Referring to FIGS. 6 and 7, the second semiconductor layer SEM2 of the first type light-emitting element LE1T may include a first portion SEM2_1 having a first thickness d1 and a second portion SEM2_2 having a second thickness d2. The second thickness d2 may be less than the first thickness d1.

An active layer MQW may be located on one surface of the first portion SEM2_1.

The protective layer INS1 of the first type light-emitting element LE1T may include a first opening OP1 and a second opening OP2. The first opening OP1 may overlap the first portion SEM2_1 in the thickness direction DR3, and the second opening OP2 may overlap the second portion SEM2_2 in the thickness direction DR3. The first opening OP1 may expose one side of the first semiconductor layer SEM1 (or conductive layer), and the second opening OP2 may expose one side of the second portion SEM2_2 of the second semiconductor layer SEM2.

The contact electrode CTE overlaps the first opening OP1 and is connected to one side of the first semiconductor layer SEM1 (or conductive layer) exposed through the first opening OP1.

One side of the second portion SEM2_2 of the second semiconductor layer SEM2 exposed through the second opening OP2 may be connected to a connect electrode CNE, described later.

The second type light-emitting element LE2T may have a rectangular cross-section in which a width of the top surface is approximately the same as a width of the bottom surface, but is not limited thereto, and the light-emitting element LE may have an inverted tapered cross-section shape in which a width of the top surface is wider than a width of the bottom surface.

The width of the active layer MQW of the first type light-emitting element LE1T and the width of the active layer MQW of the second type light-emitting element LE2T may be substantially the same (e.g., in plan view).

The protective layer INS of the second type light-emitting element LE2T may have one opening (the third opening OP3) on one side of the first semiconductor layer SEM1. One side of the first semiconductor layer SEM1 (or conductive layer) exposed through the second opening OP2 may be connected to a connect electrode CNE described later. That is, the connect electrode CNE may electrically connect the first type light-emitting element LE1T and the second type light-emitting element LE2T. For example, the connect electrode CNE may connect the second semiconductor layer SEM2 of the first type light-emitting element LE1T and the first semiconductor layer SEM1 of the second type light-emitting element LE2T, thereby connecting the first type light-emitting element LE2T and the second type light-emitting element LE2T in series.

The second type light-emitting element LE2T further includes a dummy electrode DE located on the protective layer INS. The dummy electrode DE may be formed of the same material as the contact electrode CTE. The thickness of the dummy electrode DE may be the same as the thickness of the contact electrode CTE. The dummy electrode DE may be located on the second pixel electrode PXE2. The dummy electrode DE is located on one side (e.g., a lower side) of the first semiconductor layer SEM1 where the third opening OP3 is located, and is spaced apart from the third opening OP3. Therefore, the dummy electrode DE is not electrically connected to the semiconductor layer of the second type light-emitting element LE2T, and only serves to compensate for the step with the first type light-emitting element LE1T so that the second type light-emitting element LE2T is not tilted. The dummy electrode DE may also be referred to as a non-contact electrode, meaning that it is not electrically connected to the semiconductor layer of the second type light-emitting element LE2T.

A width of the dummy electrode DE may be less than a width of the contact electrode CTE.

A bonding electrode BOD may be located between the dummy electrode DE and the pixel electrode PXE2. The bonding electrode BOD may serve as a bonding metal for bonding the pixel electrode PXE2 and the second type light-emitting element LE2T during the manufacturing process. For example, the bonding electrode BOD may include at least one of gold (Au), copper (Cu), tin (Sn), silver (Ag), aluminum (Al), or titanium (Ti). For example, the bonding electrode BOD may include a 9:1 alloy, an 8:2 alloy, or a 7:3 alloy of gold and tin.

The connect electrode CNE may be formed of a transparent conductive oxide (TCO) such as, but not limited to, indium tin oxide (ITO) or indium zinc oxide (IZO), and may include one or more of molybdenum (Mo), aluminum (Al), chromium (Cr), gold (Au), titanium (Ti), nickel (Ni), neodymium (Nd), or copper (Cu).

A filling layer (e.g., filling material) FM is located between the side walls of the first type light-emitting element LE1T and the second type light-emitting element LE2T. The filling layer FM contacts a side surface SF1 of the first type light-emitting element LE1T, and a side surface SF2 of the second type light-emitting element LE2T, the side surfaces SF1 and SF2 corresponding to where the first type light-emitting element LE1T and the second type light-emitting element LE2T face each other.

The filling layer FM may increase the structural support capacity of the first type light-emitting element LE1T and the second type light-emitting element LE2T. The filling layer FM may be a material having insulating properties. The filling layer FM may include for example, an inorganic insulating material, such as silicon oxide (SiOₓ), silicon nitride (SiNₓ), silicon oxynitride (SiOₓN_{y}), aluminum oxide (AlₓO_{y}), aluminum nitride (AlN), and/or the like. Alternatively, the filling layer FM may include an organic insulating material, for example, an epoxy-based resin, an acrylic-based resin, a cardo-based resin, or an imide-based resin. The surface of the filling layer FM (a surface in contact with the side surface S1 of the first type light-emitting element LE1T and the side surface S2 of the second type light-emitting element LE2T) may include a reflective material to form a light reflective surface. When a light reflective surface is formed on the surface of the filling layer FM, the light emission efficiency of the first type light-emitting element LE1T and the second type light-emitting element LE2T may be improved. In some embodiments, the filling layer FM may include a light-absorbing material (e.g., an inorganic black pigment, such as carbon black or an organic black pigment). When a light-absorbing surface is formed on the surface of the filling layer FM, interference the light emitted from the first type light-emitting element LE1T and the light emitted from the second type light-emitting element LE2T may be reduced or prevented.

Each of the third type light-emitting elements LE may have a rectangular cross-section in which the width of the top surface is almost the same as the width of the bottom surface, but is not limited thereto, and the light-emitting elements LE may have an inverted tapered cross-sectional shape in which the width of the top surface is wider than the width of the bottom surface.

The protective layer INS of the third type light-emitting element LE may include an opening on one side facing the pixel electrode PXE1 and PXE3. The first semiconductor layer SEM1 of the third type light-emitting element LE is exposed by the opening. A contact electrode CTE is located on the exposed first semiconductor layer SEM1 of the third type light-emitting element LE.

A bonding electrode BOD may be located between the pixel electrode PXE1 and PXE3 and the contact electrode CTE.

The third organic layer 190 is a layer for flattening or planarizing a step caused by the plurality of light-emitting elements LE. The third organic layer 190 may cover the plurality of light-emitting elements LE1T, LE2T, and LE. In one or more embodiments, the third organic layer 190 is located to cover the plurality of light-emitting elements LE1T, LE2T, and LE but is not limited thereto. If the third organic layer 190 is located to cover only a portion of the side surfaces of the plurality of light-emitting elements LE1T, LE2T, and LE, an additional organic film may be located on the third organic layer 190 to cover all the plurality of light-emitting elements LE1T, LE2T, and LE. Meanwhile, a fourth opening OP4 exposing at least a portion of the top surface (other surface) of the second type light-emitting element LE2T and the third type light-emitting element LE1T may be included.

The third organic layer 190 may be formed of an organic film, such as an acrylic resin, an epoxy resin, a phenolic resin, a polyamide resin, a polyimide resin, or the like.

The common electrode CE is located on the third organic layer 190 and may be connected to the top surface (other surface) of the second type light-emitting element LE2T and the third type light-emitting element LE1T exposed through the fourth opening OP4. On the other hand, the first type light-emitting element LE is not in direct contact with the common electrode CE.

The common electrode CE may be a common layer formed commonly on the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO), which may transmit light.

Meanwhile, the pixel electrodes PXE1, PXE2, and PXE3 may be referred to as an anode electrode or a first electrode, and the common electrode CE may be referred to as a cathode electrode or a second electrode.

The first capping layer CAP1 may be located on the common electrode CE.

A light-blocking layer BM, a first light conversion layer QDL1, a second light conversion layer QDL2, and/or a light transmission layer TPL may be located on the first capping layer CAP1. The first light conversion layer QDL1, the second light conversion layer QDL2, and the light transmission layer TPL may be formed corresponding to compartments of the light-blocking layer BM. Therefore, the first light conversion layer QDL1 may be located on the first capping layer CAP1 in the first sub-pixel SPX1, the second light conversion layer QDL2 may be located on the first capping layer CAP1 in the second sub-pixel SPX2, and the light transmission layer TPL may be located on the first capping layer CAP1 in the third sub-pixel SPX3. The light-blocking layer BM overlaps the third organic layer 190 in the third direction DR3, and may not overlap the plurality of light-emitting elements LE.

The first light conversion layer QDL1 may convert a portion of the third light (light in the blue wavelength band) incident from the light-emitting element LE into first light (light in the green wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light-emitting element LE into first light (light in the green wavelength band).

The second light conversion layer QDL2 may convert a portion of the third light (light in the blue wavelength band) incident from the light-emitting element LE into second light (light in the red wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light-emitting element LE into second light (light in the red wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots (QD), quantum rods, fluorescent materials, or phosphorescent materials.

The light-blocking layer BM may include a first light-blocking layer BM1 and a second light-blocking layer BM2 that are sequentially stacked. A length of the first light-blocking layer BM1 in the first direction DR1 or the second direction DR2 may be wider than a length of the second light-blocking layer BM2 in the first direction DR1 or the second direction DR2. The first light-blocking layer BM1 and the second light-blocking layer BM2 may be formed of an organic film, such as an acrylic resin, an epoxy resin, a phenolic resin, a polyamide resin, a polyimide resin, or the like. The first light-blocking layer BM1 and the second light-blocking layer BM2 may include a light-blocking material to reduce or prevent light from the light-emitting element LE of one sub-pixel proceeding to the neighboring sub-pixel. For example, the first light-blocking layer BM1 and the second light-blocking layer BM2 may include an inorganic black pigment, such as carbon black or an organic black pigment.

The second capping layer CAP2 may be located on the first capping layer CAP1 and the light-blocking layer BM. The second capping layer CAP2 may be located on the side and top surfaces of the light-blocking layer BM. That is, the second capping layer CAP2 may be located on the side of the first light-blocking layer BM1 and the side and top surfaces of the second light-blocking layer BM2.

The reflective film RF may be located between the light-blocking layer BM and the first light conversion layer QDL1, between the light-blocking layer BM and the second light conversion layer QDL2, and between the light-blocking layer BM and the light transmission layer TPL. The reflective film RF may be located on a second capture layer CAP2 located on the side of the first light-blocking layer BM1 and the side of the second light-blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material, such as aluminum (Al). The thickness of the reflective film RF may be approximately 0.1 μm.

Alternatively, the reflective layer RF may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, silicon nitride (SiNₓ), silicon oxide (SiON), silicon oxide (SiOₓ), titanium oxide (TiOₓ), or aluminum oxide (AlOₓ).

The third capping layer CAP3 may be located on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), or aluminum oxide (AlOₓ). The first light conversion layer QDL1, the second capping layer CAP2, and the third capping layer CAP3 may be encapsulated by the first capture layer CAP1, the second capping layer CAP2, and the third capping layer CAP3.

A fifth organic film 213 may be located on the third capping layer CAP3. A plurality of color filters CF1, CF2, and CF3 may be located on the fifth organic film 213. The plurality of color filters CF1, CF2, and CF3 may include first color filters CF1, second color filters CF2, and third color filters CF3.

The first color filter CF1 located in the first sub-pixel SPX1 may transmit the first light (light in the green wavelength band), and may absorb or block the third light (light in the blue wavelength band). Therefore, the first color filter CF1 may transmit the first light (light in the green wavelength band) that has been converted by the first light conversion layer QDL1 among the third light (light in the blue wavelength band) emitted from the light-emitting element LE, and may absorb or block the third light (light in the blue wavelength band) that has not been converted by the first light conversion layer QDL1. Accordingly, the first sub-pixel SPX1 may emit the first light (light in the green wavelength band).

The second color filter CF2 located in the second sub-pixel SPX2 may transmit the second light (light in the red wavelength band), and may absorb or block the third light (light in the blue wavelength band). Therefore, the second color filter CF2 may transmit the second light (light in the red wavelength band) that has been converted by the first light conversion layer QDL1 among the third light (light in the blue wavelength band) emitted from the light-emitting element LE, and may absorb or block the third light (light in the blue wavelength band) that has not been converted by the first light conversion layer QDL1. Accordingly, the second sub-pixel SPX2 may emit the second light (light in the red wavelength band).

The third color filter CF3 located in the third sub-pixel SPX3 may transmit the third light (light in the blue wavelength band). Therefore, the third color filter CF3 may transmit the third light (light in the blue wavelength band) emitted from the light-emitting element LE passing through the light transmission layer TPL. Accordingly, the third sub-pixel SPX3 may emit the third light (light in the blue wavelength band).

The first color filter CF1, the second color filter CF2, and the third color filter CF3 overlapping in the third direction DR3 may overlap with the light-blocking layer BM in the third direction DR3.

A sixth organic film 214 for planarization may be located on the plurality of color filters CF1, CF2, and CF3.

The fifth organic film 213 and the six organic film 214 may be formed from an acrylic resin, an epoxy resin, a phenolic resin, a polyamide resin, a polyimide resin, or the like.

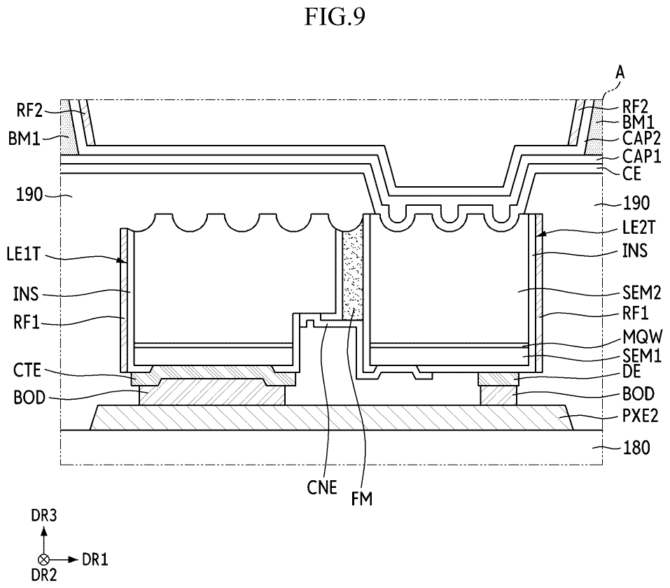

FIG. 9 is a cross-sectional view illustrating an example of area A of FIG. 6 according to one or more other embodiments in detail.

The one or more embodiments corresponding to FIG. 9 differs from the one or more embodiments corresponding to FIG. 7 in that a first reflective layer RF1 is located on at least one side of the first type light-emitting element LE1T and at least one side of the second type light-emitting element LE2T. In the one or more embodiments corresponding to FIG. 9, the description overlapping with the one or more embodiments corresponding to FIG. 7 is omitted.

The first reflective layer RF1 may be located on at least one side of the side of the first type light-emitting element LE1T and at least one side of the second type light-emitting element LE2T, and for example, the first reflective layer RF1 may be located on sides other than, or opposite to, the respective sides corresponding to where the first type light-emitting element LE1T and the second type light-emitting element LE2T face each other.

The first reflective layer RF1 serves to reflect light that is emitted from the active layer MQW of the first type light-emitting element LE1T and the second type light-emitting element LE2T, and travels in a lateral direction.

The first reflective layer RF1 may include a highly reflective metal material, such as aluminum (Al). The thickness of the first reflective layer RF1 may be approximately 0.1 μm.

Alternatively, the first reflective layer RF1 may include M pairs of first layers and second layers (M is an integer greater than or equal to 2) having different refractive indices to function as distributed Bragg reflectors (DBR). In this case, the M first layers and the M second layers may be alternately located. The first layer and the second layer may be formed from inorganic films, for example, silicon nitride (SiNₓ), silicon oxide (SiON), silicon oxide (SiOₓ), titanium oxide (TiOₓ), or aluminum oxide (AlOₓ).

In one or more other embodiments, the first reflective layer RF1 may be located on the entire side of the first type light-emitting element LE1T and the entire side of the second type light-emitting element LE2T.

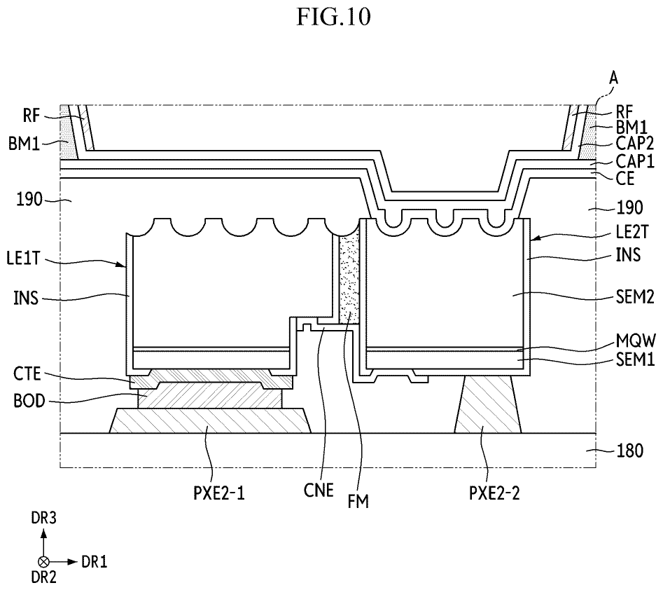

FIG. 10 is a cross-sectional view illustrating an example of area A of FIG. 6 according to one or more other embodiments in detail.

The one or more embodiments corresponding to FIG. 10 differs from the one or more embodiments corresponding to FIG. 7 in that the second type light-emitting element LE2T does not have a dummy electrode DE, and in that the second type light-emitting element LE2T and the first type light-emitting element LE1T do not contact a single pixel electrode PXE2. In the one or more embodiments corresponding to FIG. 10, the description that is redundant with the one or more embodiments corresponding to FIG. 7 is omitted.

The first type light-emitting element LE1T may be same as the first type light-emitting element LE1T described in FIG. 7. The second type light-emitting element LE2T may be same as the second type light-emitting element LE2T described in FIG. 7 except for the dummy electrode DE.

The first type light-emitting element LE1T may be located on the second first pixel electrode PXE2-1, and the second type light-emitting element LE2T may be located on the second second pixel electrode PXE2-2.

The second first pixel electrode PXE2-1 may be formed with a first height h1, and the second second pixel electrode PXE2-2 may be formed with a second height h2. The second height h2 is higher than the first height h1. The second second pixel electrode PXE2-2 may compensate for the thickness of the contact electrode CTE and the bonding electrode BOD of the first type light-emitting element LE1T. For example, the height of the second second pixel electrode PXE2-2 be equal to the sum of the height of the contact electrode CTE of the first type light-emitting element LE1T, the height of the bonding electrode BOD, and the height of the second first pixel electrode PXE2-1. Therefore, the top surfaces of the first type light-emitting element LE1T and the second type light-emitting element LE2T may be located at the same height.

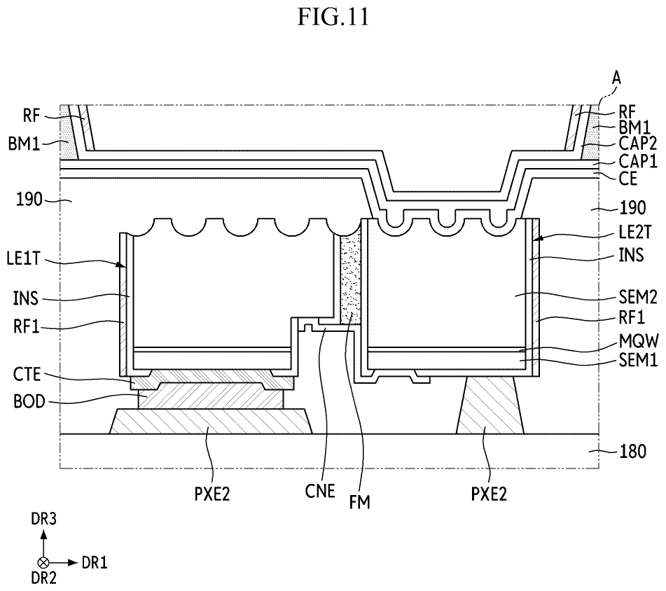

FIG. 11 is a cross-sectional view illustrating an example of area A of FIG. 6 according to one or more other embodiments in detail.

The one or more embodiments corresponding to FIG. 11 differs from the one or more embodiments corresponding to FIG. 10 in that a first reflective layer RF1 is located on at least one side of the first type light-emitting element LE1T and at least one side of the second type light-emitting element LE2T. In the one or more embodiments corresponding to FIG. 11, the description overlapping with the one or more embodiments corresponding to FIG. 10 is omitted.

The first reflective layer RF1 may be located on at least one side of the side of the first type light-emitting element LE1T and at least one side of the second type light-emitting element LE2T, and for example, the first reflective layer RF1 may be located on respective sides other than, or opposite to, the sides corresponding to where the first type light-emitting element LE1T and the second type light-emitting element LE2T face each other.

The first reflective layer RF1 serves to reflect light that is emitted from the active layer MQW of the first type light-emitting element LE1T and the second type light-emitting element LE2T and that travels in a lateral direction.

The first reflective layer RF1 may include a highly reflective metal material, such as aluminum (Al). The thickness of the first reflective layer RF1 may be approximately 0.1 μm.

Alternatively, the first reflective layer RF1 may include M pairs of first layers and second layers (M is an integer greater than or equal to 2) having different refractive indices to function as distributed Bragg reflectors (DBR). In this case, the M first layers and the M second layers may be alternately located. The first layer and the second layer may be formed from inorganic films, for example, silicon nitride (SiNₓ), silicon oxide (SiON), silicon oxide (SiOₓ), titanium oxide (TiOₓ), or aluminum oxide (AlOₓ).

In other embodiments, the first reflective layer RF1 may be located on the entire side of the first type light-emitting element LE1T and the entire side of the second type light-emitting element LE2T. The first reflective layer RF1 may surround the side of the first type light-emitting element LE1T, and the first reflective layer RF1 may surround the side of the second type light-emitting element LE2T.

Hereinafter, a manufacturing process of a display device 10 according to one or more embodiments will be described with reference to other drawings.

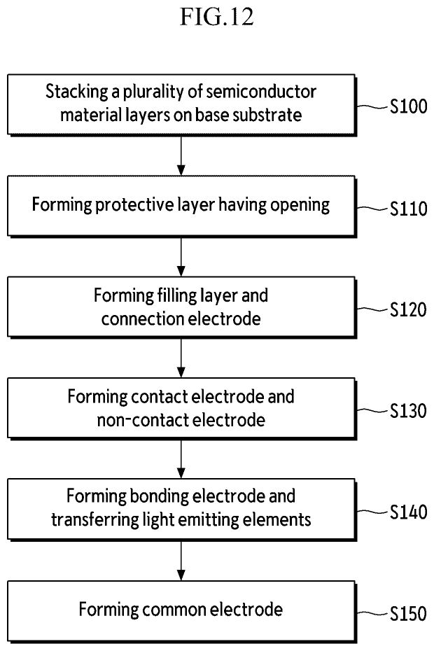

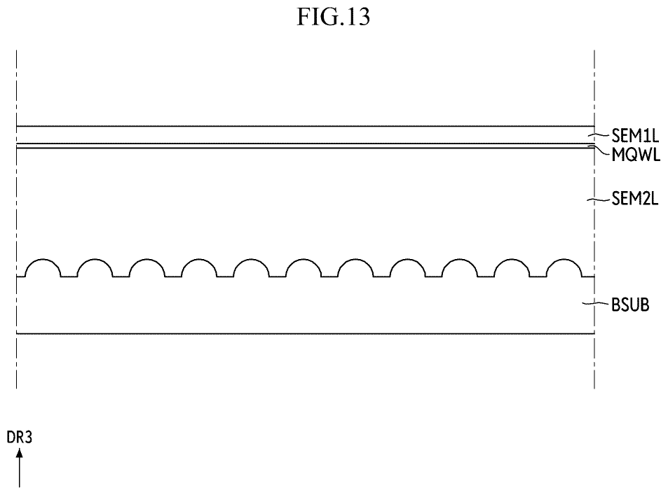

FIG. 12 is a flowchart illustrating a method of manufacturing a display device according to one or more embodiments. FIGS. 13 to 25 are drawings to illustrate a method of manufacturing a display device according to one or more embodiments.

FIGS. 13 to 25 illustrate the structure of each layer of the display device 10 in the order of formation, respectively in cross-sectional view. FIGS. 13 to 25 illustrate the manufacturing process of the first type light-emitting element (LE1T) and the second type light-emitting element (LE2T) of the display device 10, which may roughly correspond to the cross-sectional views of FIG. 7. In addition, the following mainly illustrates the second sub-pixel SPX2 of the display device 10. In the following, a manufacturing method of the display device illustrated in FIGS. 13 to 25 will be described in connection with FIG. 12.

First, referring to FIGS. 13 to 15, a plurality of semiconductor material layers are laminated on a base substrate BSUB and mesa-patterned to form a plurality of semiconductor layer stacks (S100 in FIG. 12)

Referring to FIG. 13, a base substrate BSUB is prepared. The base substrate BSUB may be a sapphire substrate (Al₂O₃) or a silicon wafer containing silicon. However, it is not limited thereto, and in one or more embodiments, a case in which the base substrate BSUB is a sapphire substrate is described as an example.

A plurality of semiconductor material layers SEM2L, MQWL, and SEM1L are formed on a base substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), plasma laser deposition (PLD), dual-type thermal evaporation, sputtering, metal organic chemical vapor deposition (MOCVD), and/or the like, and may be formed by metal organic chemical vapor deposition (MOCVD). However, it is not limited thereto.

A precursor material for forming the plurality of semiconductor material layers is not particularly limited within the range that may be conventionally selected for forming the subject material. In one example, the precursor material may be a metal precursor including an alkyl group, such as a methyl or ethyl group. For example, it may be a compound, such as trimethyl gallium (Ga(CH₃)₃), trimethyl aluminum (Al(CH₃)₃), triethyl phosphate ((C₂H₅)₃PO₄), etc., but are not limited thereto.

For example, a second semiconductor material layer SEM2L, an active material layer MQWL, and a first semiconductor material layer SEM1L are sequentially formed on a base substrate BSUB. In some embodiments, a conductive layer may be further formed on the first semiconductor material layer SEM1L.

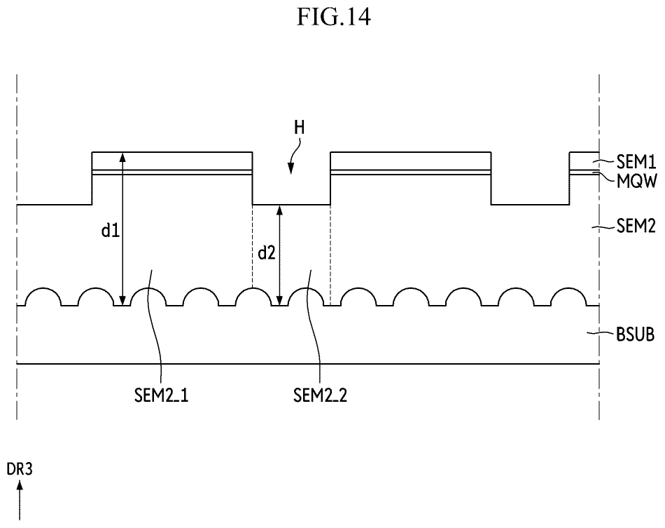

Next, referring to FIGS. 13 and 14, a concave groove H is formed downwardly on a plurality of semiconductor material layers by an etching process.

The concave groove H may penetrate the first semiconductor material layer SEM1L and the active layer MQWL, and may be formed up to at least a portion of the second semiconductor material layer SEM2L. To this end, a plurality of first mask patterns are formed on the first semiconductor material layer SEM1L. The first mask pattern may be a hard mask including an inorganic material or a photoresist mask including an organic material. The first mask pattern reduces or prevents the likelihood of the lower plurality of semiconductor material layers SEM2L, MQWL, and SEM1L being etched. Then, a portion of the plurality of semiconductor material layers may be etched (1^{st} etch) using the plurality of first mask patterns as a mask to form the groove H. Accordingly, the second semiconductor layer SEM2 includes a first portion SEM2_1 having a first thickness d1 and a second portion SEM2_2 having a second thickness d2 overlapping the groove H.

The semiconductor material layers may be etched by a conventional method. For example, the process for etching the semiconductor material layers may be dry etching, wet etching, reactive ion etching (RIE), deep reactive ion etching (DRIE), inductively coupled plasma reactive ion etching (ICP-RIE), or the like. In the case of the dry etching method, anisotropic etching is possible, which may be suitable for vertical etching. When the etching method described above is used, the etchant may be Cl₂ or O₂, etc. However, it is not limited thereto.

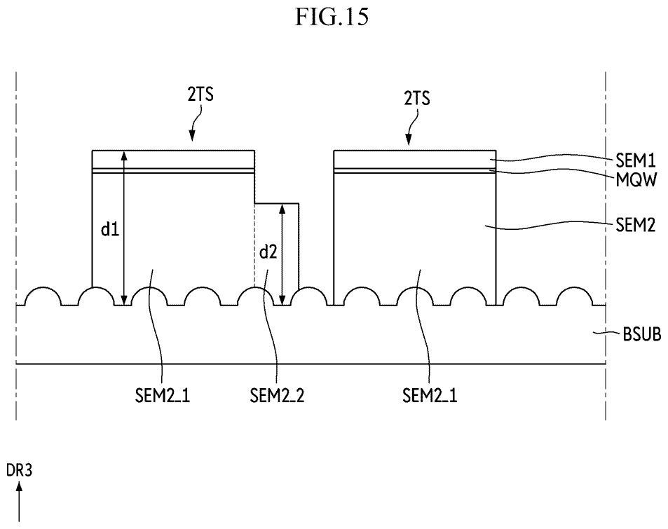

Next, referring to FIG. 15, a plurality of semiconductor material layers SEM2L, MQWL, and SEM1L are etched in a mesa shape to form a plurality of semiconductor layer stacks SEM2, MQW, and SEM1. The plurality of semiconductor layer stacks may include a configuration in which a second semiconductor layer SEM2, an active layer MQW, and a first semiconductor layer SEM1 are sequentially stacked.

To this end, a plurality of second mask patterns are formed on the first semiconductor layer SEM1. The second mask pattern may be a hard mask including an inorganic material or a photoresist mask including an organic material. The second mask pattern reduces or prevents the likelihood of the lower plurality of semiconductor material layers SEM2L, MQWL, and SEM1L being etched. Then, a portion of the plurality of semiconductor material layers is etched (2^{nd} etch) using the plurality of second mask patterns as a mask to form a semiconductor layer stack.

On the base substrate BSUB, the plurality of semiconductor material layers SEM2L, MQWL, and SEM1L non-overlapping with the second mask pattern may be etched and removed, and the non-etched portion overlapping with the second mask pattern may be formed into a plurality of semiconductor layer stacks.

The semiconductor stack has a first type stack 1TS that includes both a first portion SEM2_1 having a first thickness d1 and a second portion SEM2_2 having a second thickness d2, and a second type stack 2TS that includes only the first portion SEM2_1 having the first thickness d1. The first type stack 1TS and the second type stack 2TS are located adjacent to each other.

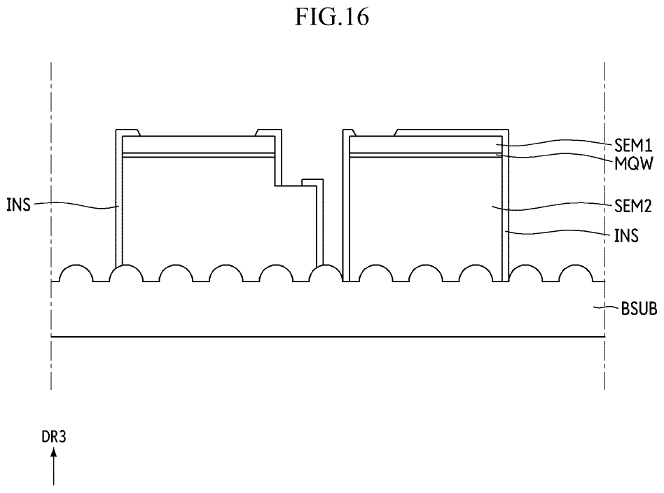

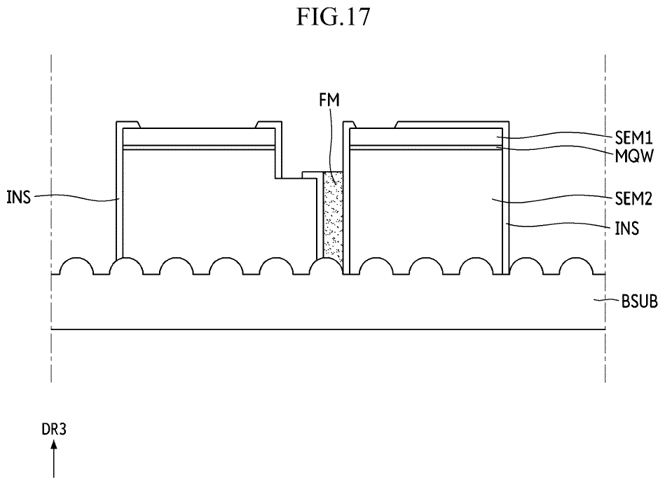

Next, referring to FIGS. 16 and 17, a protective layer INS having openings OP1, OP2, and OP3 is formed (S110 in FIG. 12)

For example, an insulating material layer is formed on the outer surface of the semiconductor layer stack 1TS and 2TS. The insulating material layer is formed on the entire surface of the base substrate BSUB, and may be formed not only on the semiconductor layer stack 1TS and 2TS, but also may be formed on the top surface of the base substrate BSUB exposed by the semiconductor layer stack 1TS and 2TS.

Then, etching is performed to partially remove the insulating material layer to form a protective layer INS having openings OP1, OP2, and OP3 on the top surface of the semiconductor layer stack 1TS and 2TS.

The protective layer INS is formed that surrounds the first type stack 1TS, has a first opening OP1 that overlaps the first portion SEM2_1 in the thickness direction, and a second opening OP2 that overlaps the second portion SEM2_2 in the thickness direction. The first semiconductor layer SEM1 is exposed by the first opening OP1 and the second semiconductor layer SEM2 is exposed by the second opening OP2. The protective layer INS is formed surrounding the second type stack 2TS and having a third opening OP3 on the top surface. The first semiconductor layer SEM1 is exposed by the third opening OP3.

The process of partially removing the insulating material layer may be performed by a process, such as an etch-back after dry etching, which is an anisotropic etching but is not limited thereto.

Next, a filling layer FM and a connect electrode CNE are formed (S120 in FIG. 12).

Referring to FIG. 17, a filling layer FM is formed by filling an insulating filling material between the first type stack 1TS and the second type stack 2TS. The filling layer FM may be formed by applying using a solution process, such as inkjet printing and patterning through an exposure process. The filling layer FM reduces the step between the first type stack 1TS and the second type stack 2TS, and reduces the difficulty of manufacturing the subsequent connect electrode CNE.

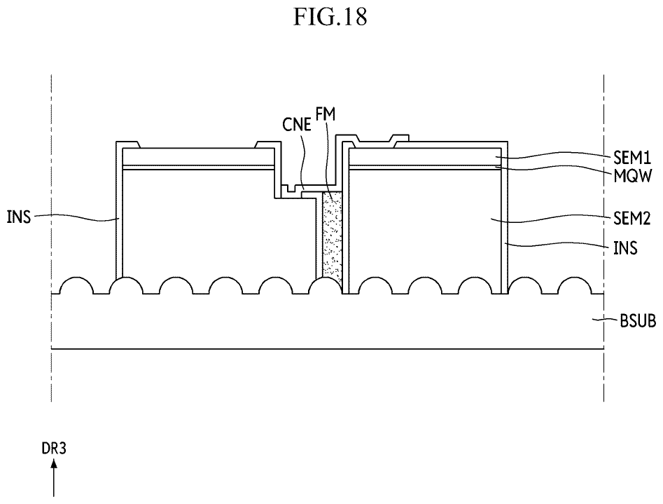

Referring to FIG. 18, for example, an electrode material layer is laminated on the entire surface of the base substrate BSUB to cover the top surfaces of the first type stack ITS and the second type stack 2TS, and then a portion of the electrode material layer is etched through an etching process to form a connect electrode CNE connecting the second semiconductor layer SEM2 exposed by the second opening OP2 of the first type stack 1TS, and the first semiconductor layer SEM1 exposed by the third opening OP3 of the second type stack 2TS. The first type stack 1TS and the second type stack 2TS are connected in series by the connect electrode CNE.

Next, a contact electrode CTE and a non-contact electrode DE are formed (S130 in FIG. 12).

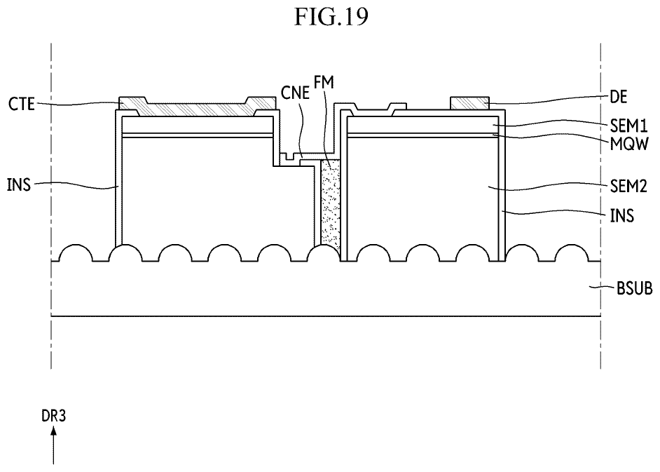

Referring to FIG. 19, a contact electrode CTE electrically connected to the first semiconductor layer SEM1 is formed on the first opening OP1 of the first type stack ITS. A non-contact electrode DE is formed on the protective layer INS of the second type stack 2TS.

For example, a mask covering the upper portion of the connect electrode CNE is formed, and then an electrode material layer is laminated on the entire surface of the base substrate BSUB to cover the top surfaces of the first type stack 1TS and the second type stack 2TS, and then a portion of the electrode material layer is etched through an etching process. In this way, a contact electrode CTE is formed on the first type stack 1TS, and a non-contact electrode DE is formed on the second type stack 2TS.

Because the non-contact electrode DE may be formed at the same height when forming the contact electrode CTE, the number of processes may be reduced compared to the process of forming the non-contact electrode DE at a different height when forming the contact electrode CTE.

In this way, the first type stack 1TS becomes a first type light-emitting element LE1T, and the second type stack 2TS becomes a second type light-emitting element LE2T.

Next, a bonding electrode BOD is formed, and the light-emitting elements LE1T and LE2T are transferred onto a pixel electrode PXE2 of a circuit board (S140 in FIG. 12).

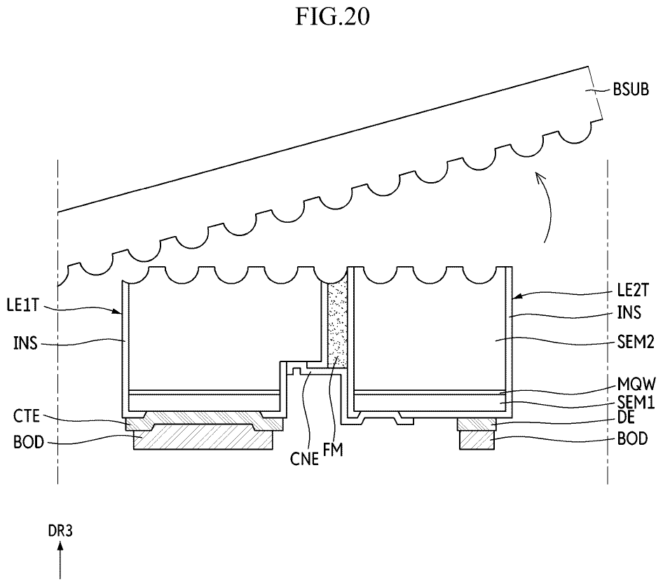

Referring to FIG. 20, an electrode material layer for a bonding electrode is laminated on the entire surface of a base substrate BSUB to cover the first type light-emitting element LE1T and the second type light-emitting element LE2T, and then a portion of the electrode material layer is etched through an etching process. As a result, a bonding electrode BOD that overlaps a contact electrode CTE and a non-contact electrode DE may be formed.

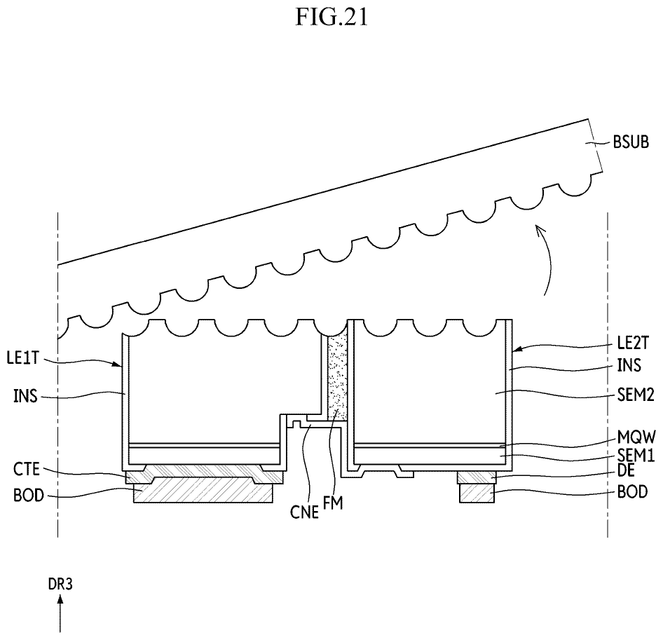

Referring to FIG. 21, a first type light-emitting element LE1T and a second type light-emitting element LE2T may be separated from the base substrate BSUB.

The process of separating the base substrate BSUB may be separated by, for example, a laser lift-off (LLO) process. The laser lift-off process uses a laser, and a KrF excimer laser (e.g., about 248 nm wavelength) may be used as a source, but is not limited thereto. The first type light-emitting element LE1T and the second type light-emitting element LE2T may be separated from the base substrate BSUB by irradiating the base substrate BSUB with a laser.

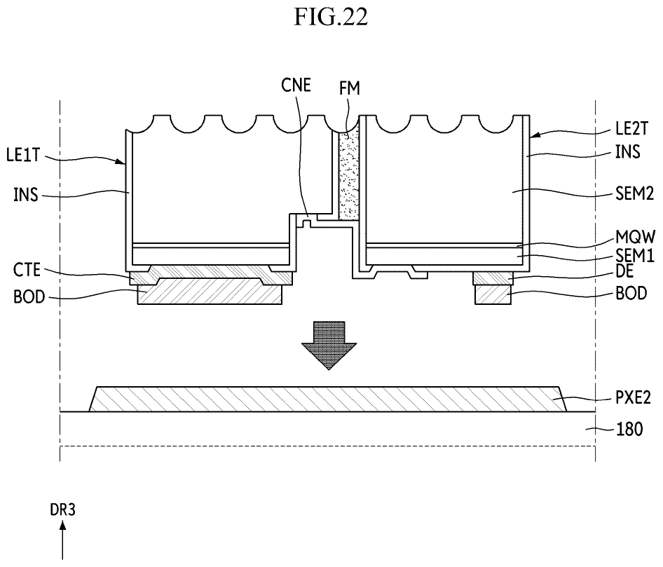

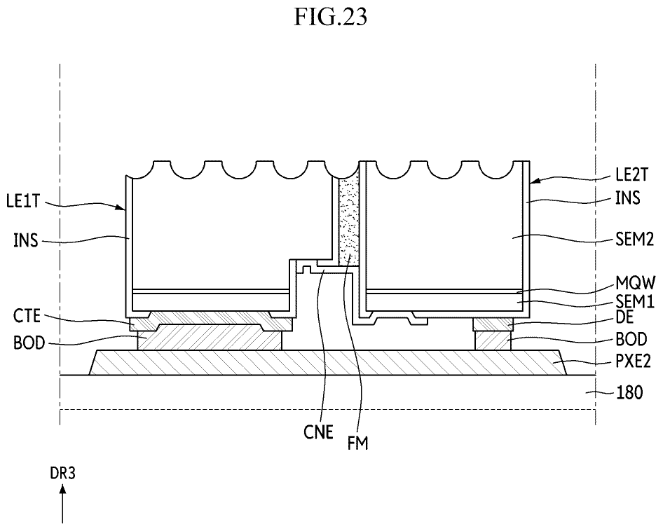

Referring to FIGS. 22 and 23, the first type light-emitting element LE1T and the second type light-emitting element LE2T are located on the pixel electrode PXE2, and heat and pressure are applied to the bonding electrode BOD to bond the first type light-emitting element LE1T and the second type light-emitting element LE2T on the pixel electrode PXE2.

Then, a common electrode in contact with the second type light-emitting element LE2T is formed (S150 in FIG. 12).

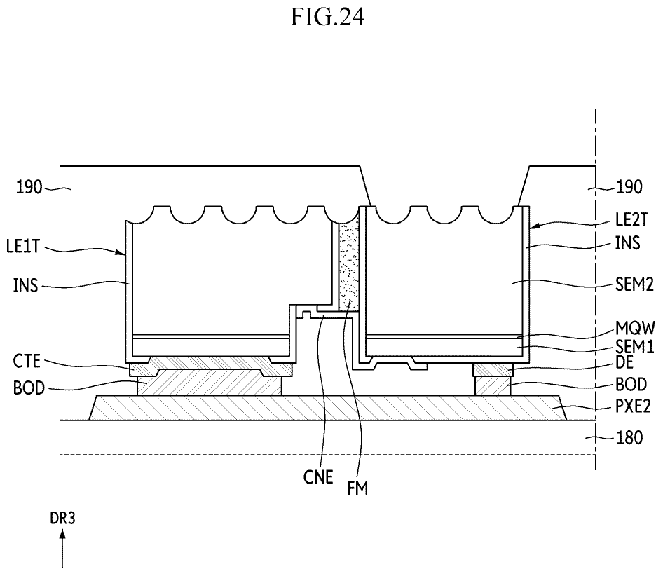

Referring to FIG. 24, a third organic layer 190 is formed on the substrate 110 to which the first type light-emitting element LE1T and the second type light-emitting element LE2T are bonded. The third organic layer 190 may be formed to fill the space between the first type light-emitting element LE1T and the second type light-emitting element LE2T to cover both the first type light-emitting element LE1T and the second type light-emitting element LE2T.

A fourth opening OP4 overlapping the second type light-emitting element LE2T is formed in the third organic layer 190 using a mask. At least a portion of the second semiconductor layer SEM2 of the second type light-emitting element LE2T may be exposed by the fourth opening OP4. The common electrode CE does not directly contact the first type light-emitting element LE1T.

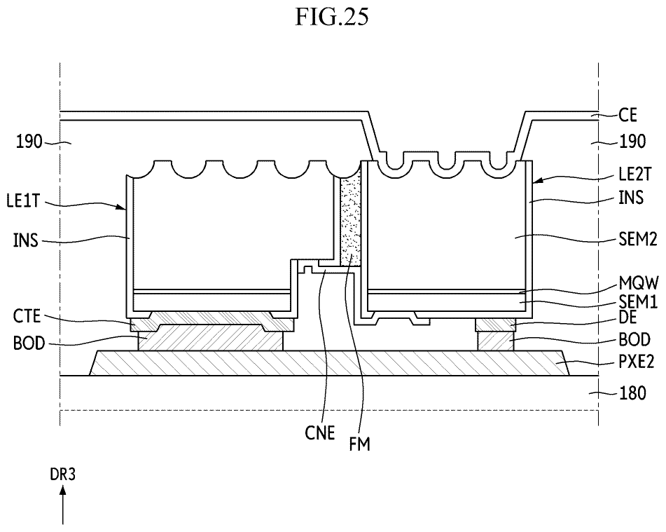

Referring to FIG. 25, the common electrode CE covers the first type light-emitting element LE1T, the second type light-emitting element LE2T, and the third organic layer 190, and may be formed to directly contact the second type light-emitting element LE2T through the fourth opening OP4. The common electrode CE may be formed along the unevenness of the top surface of the third semiconductor SEM3 of the light-emitting element LE. The common electrode CE may be formed continuously over the entire display area.

Then, as shown in FIGS. 6 and 7, a capping layer, a partition wall, a wavelength conversion layer, a light transmission layer, and a color filter layer are formed sequentially.

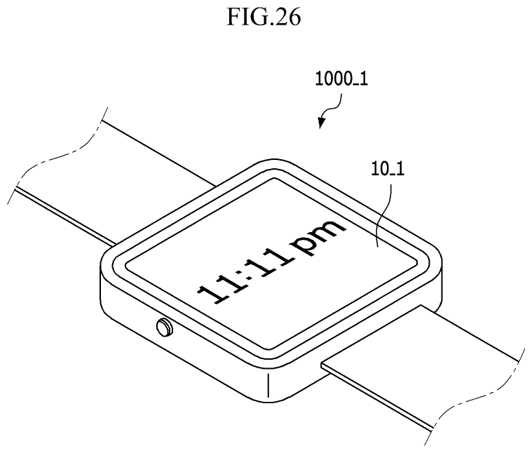

FIG. 26 is a view of a smart watch including a display device according to one or more embodiments.

Referring to FIG. 26, a display device 10_1 according to one or more embodiments may be applied to a smart watch 1000_1, which is one of smart devices.

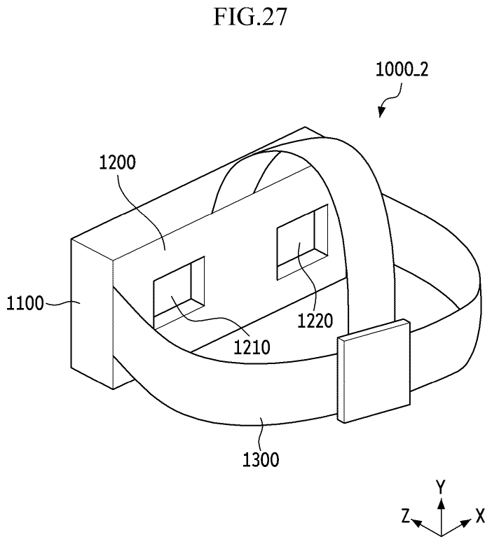

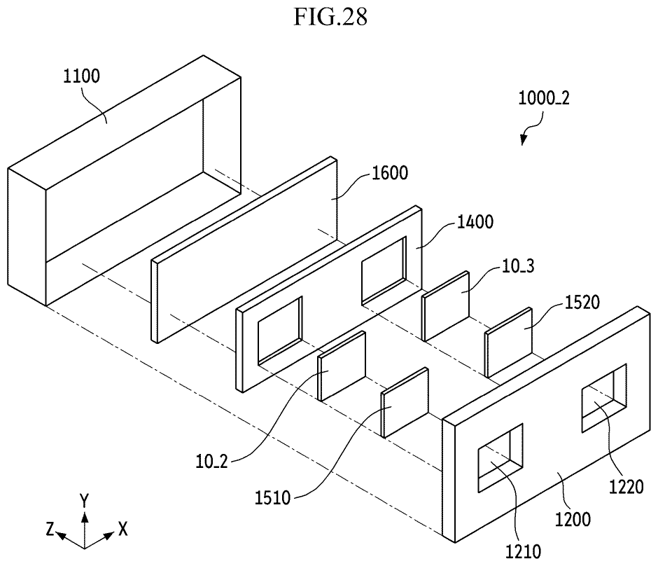

FIGS. 27 and 28 are views of a virtual reality (VR) device including a display device according to one or more embodiments.

Referring to FIGS. 27 and 28, a head-mounted display device 1000_2 according to one or more embodiments includes a first display device 10_2, a second display device 10_3, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be located between the first display device 10_2 and the first eyepiece 1210. The second optical member 1520 may be located between the second display device 10_3 and the second eyepiece 1220. Each of the first optical member 1510 and the second optical member 1520 may include at least one convex lens.

The middle frame 1400 may be located between the first display device 10_2 and the control circuit board 1600, and may be located between the second display device 10_3 and the control circuit board 1600. The middle frame 1400 supports and fixes the first display device 10_2, the second display device 10_3, and the control circuit board 1600.

The control circuit board 1600 may be located between the middle frame 1400 and the display device housing 1100. The control circuit board 1600 may be connected to the first display device 10_2 and the second display device 10_3 through a connector. The control circuit board 1600 may convert an image source received from the outside into digital video data DATA, and may transmit the digital video data DATA to the first display device 10_2 and the second display device 10_3 through the connector.

The control circuit board 1600 may transmit the digital video data DATA corresponding to a left image optimized for a user's left eye to the first display device 10_2, and may transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are located separately in FIGS. 33 and 34, embodiments of the present specification are not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

The head-mounted band 1300 fixes the display device housing 1100 to a user's head so that the first eyepiece 1210 and the second eyepiece 1220 of the housing cover 1200 are kept placed on the user's left and right eyes, respectively. When the display device housing 1200 is implemented to be lightweight and small, the head-mounted display device 1000_2 may include an eyeglass frame as illustrated in FIG. 33 instead of the head-mounted band 1300.

In addition, the head-mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi® module, or a Bluetooth® module (Wi-Fi® being a registered trademark of the non-profit Wi-Fi Alliance, and Bluetooth® being a registered trademark of Bluetooth Sig, Inc., Kirkland, WA).

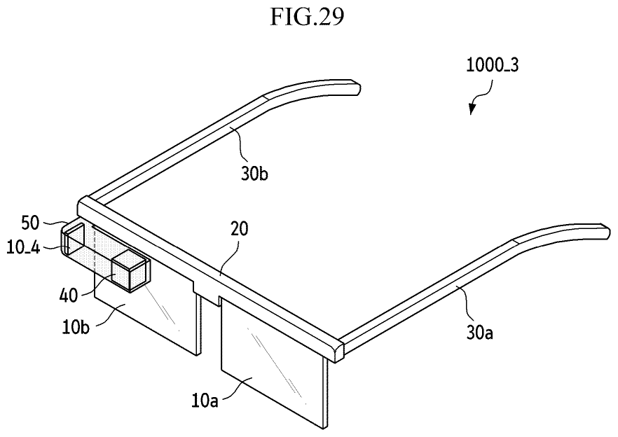

FIG. 29 is a view of a VR device including a display device according to one or more embodiments. FIG. 29 illustrates a VR device 1000_3 to which a display device 10_4 according to one or more embodiments has been applied.

Referring to FIG. 29, the VR device 1000_3 according to one or more embodiments may be a device in the form of glasses. The VR device 1000_3 may include the display device 10_4, a left lens 10a, a right lens 10b, a support frame 20, eyeglass frame legs 30a and 30b, a reflective member 40, and a display device housing 50.

In FIG. 29, a case where the VR device 1000_3 is a glasses-type display device including the eyeglass frame legs 30a and 30b is illustrated as an example. That is, the VR device 1000_3 is not limited to the one illustrated in FIG. 35 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is located at a right end of the support frame 20 in FIG. 36, embodiments of the present specification are not limited thereto. For example, the display device housing 50 may also be located at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be located at both the right end and the left end of the support frame 20. In this case, the user may view a VR image displayed on the display device 10_4 through both the left eye and the right eye.

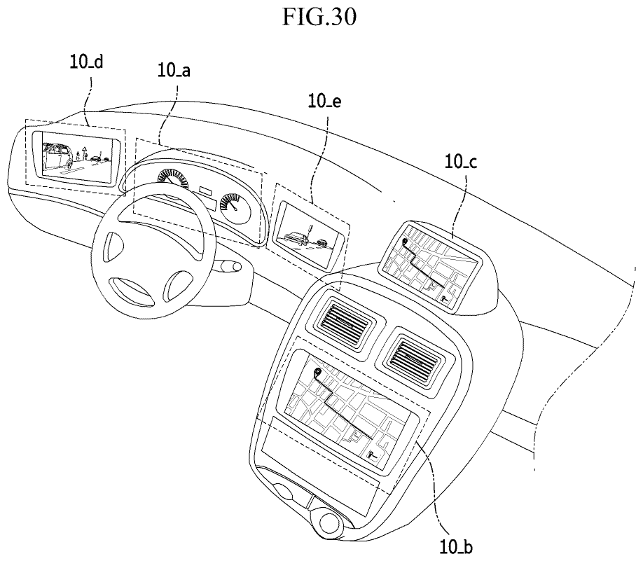

FIG. 30 is a view illustrating a vehicle instrument cluster and center fascia including display devices according to one or more embodiments. FIG. 30 illustrates a vehicle to which display devices 10_a through 10_e according to one or more embodiments have been applied.

Referring to FIG. 30, the display devices 10_a through 10_c may be applied to an instrument cluster of the vehicle, a center fascia of the vehicle, or a center information display (CID) located on a dashboard of the vehicle. In addition, the display devices 10_d and 10_e may be applied to room mirror displays that replace side mirrors of the vehicle.

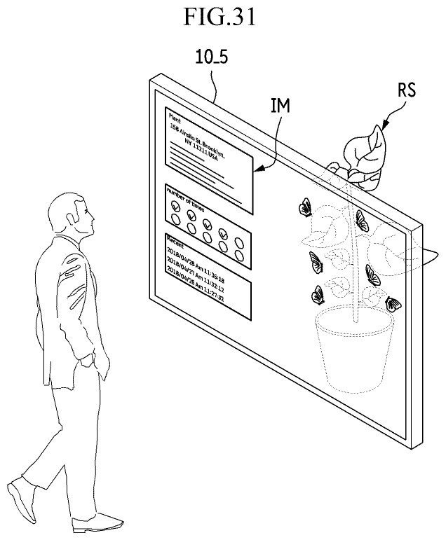

FIG. 31 is a view of a transparent display device including a display device according to one or more embodiments.

Referring to FIG. 31, a display device 10_5 according to one or more embodiments may be applied to a transparent display device. The transparent display device may transmit light while displaying an image IM. Therefore, a user located in front of the transparent display device cannot only view the image IM displayed on the display device 10_5, but also may view an object RS or the background located behind the transparent display device. When the display device 10_5 is applied to the transparent display device, a substrate of the display device 10_5 may include a light transmitting portion that can transmit light or may be made of a material that can transmit light.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A display device comprising:
a substrate;
a pixel electrode above the substrate;
a first type light-emitting element above the pixel electrode, and having a contact electrode electrically connected to the pixel electrode;
a second type light-emitting element above the pixel electrode, and having a non-contact electrode;
a filling layer between the first type light-emitting element and the second type light-emitting element;
a connect electrode connecting the first type light-emitting element and the second type light-emitting element in series; and
a common electrode above the first type light-emitting element and the second type light-emitting element, and electrically connected to the second type light-emitting element.

2. The display device of claim 1, wherein the first type light-emitting element and the second type light-emitting element comprise a first semiconductor layer, an active layer, and a second semiconductor layer,
wherein the second semiconductor layer of the first type light-emitting element comprises a first portion having a first thickness, and a second portion having a second thickness that is less than the first thickness, and
wherein the active layer and the first semiconductor layer of the first type light-emitting element overlap the first portion.

3. The display device of claim 2, wherein the first type light-emitting element further comprises a protective layer surrounding, in plan view, side surfaces of the first semiconductor layer, the active layer, and the second semiconductor layer of the first type light-emitting element, defining a first opening exposing the first semiconductor layer of the first type light-emitting element, and defining a second opening exposing the second semiconductor layer of the first type light-emitting element at the second portion, and
wherein the second type light-emitting element further comprises a protective layer surrounding side surfaces, in plan view, of the first semiconductor layer, the active layer, and the second semiconductor layer of the second type light-emitting element, and defining a third opening exposing the first semiconductor layer of the second type light-emitting element.

4. The display device of claim 3, wherein the contact electrode is electrically connected to the first semiconductor layer through the first opening, and
wherein the connect electrode connects the second semiconductor layer of the first type light-emitting element with the first semiconductor layer of the second type light-emitting element through the second opening and the third opening.

5. The display device of claim 3, wherein the non-contact electrode is on the protective layer on one surface of the second type light-emitting element.

6. The display device of claim 2, further comprising an organic layer defining a fourth opening covering the first type light-emitting element and exposing the second semiconductor layer of the second type light-emitting element.

7. The display device of claim 6, wherein the common electrode is electrically connected to the second semiconductor layer of the second type light-emitting element through the fourth opening, and overlaps, while being separated from, the first type light-emitting element in a thickness direction.

8. The display device of claim 2, wherein a width of the active layer of the first type light-emitting element is substantially equal to a width of the active layer of the second type light-emitting element.

9. The display device of claim 1, wherein the contact electrode and the non-contact electrode are at a same height.

10. The display device of claim 1, wherein the filling layer comprises an insulating material, and
wherein a surface of the filling layer comprises a light-reflecting surface or a light-absorbing surface.

11. The display device of claim 1, wherein the first type light-emitting element and the second type light-emitting element comprise a reflective layer surrounding, in plan view, at least a portion of a side surface thereof.

12. The display device of claim 1, wherein upper portions of the first type light-emitting element and the second type light-emitting element comprise a concave light extraction pattern having a hemisphere or a semi-ellipse shape.

13. The display device of claim 12, wherein the common electrode contacts the concave light extraction pattern of the second type light-emitting element.

14. A display device comprising:
a substrate;
a first pixel electrode and a second pixel electrode spaced apart from each other, and above the substrate;
a first type light-emitting element having a contact electrode above the first pixel electrode, and electrically connected to the first pixel electrode;
a bonding electrode between the first pixel electrode and the contact electrode;
a second type light-emitting element on the second pixel electrode;
a filling layer between the first type light-emitting element and the second type light-emitting element;
a connect electrode connecting the first type light-emitting element and the second type light-emitting element in series; and
a common electrode above the first type light-emitting element and the second type light-emitting element, and electrically connected to the second type light-emitting element,
wherein a height of the second pixel electrode is substantially equal to a sum of a height of the first pixel electrode, a height of the bonding electrode, and a height of the contact electrode.

15. The display device of claim 14, wherein the first type light-emitting element and the second type light-emitting element comprise a first semiconductor layer, an active layer, and a second semiconductor layer,
wherein the second semiconductor layer of the first type light-emitting element comprises a first portion having a first thickness, and a second portion having a second thickness that is less than the first thickness, and
wherein the active layer and the first semiconductor layer of the first type light-emitting element overlap the first portion.

16. The display device of claim 15, wherein the contact electrode is electrically connected to the first semiconductor layer of the first type light-emitting element, and
wherein the connect electrode connects the second semiconductor layer of the second portion of the first type light-emitting element with the first semiconductor layer of the second type light-emitting element.

17. The display device of claim 15, further comprising an organic layer covering both the first type light-emitting element and the second type light-emitting element, and having an opening exposing the second semiconductor layer of the second type light-emitting element,
wherein the common electrode is electrically connected to the second semiconductor layer of the second type light-emitting element, overlaps the first type light-emitting element in a thickness direction, and is separated from the first type light-emitting element.

18. The display device of claim 15, wherein a width of the active layer of the first type light-emitting element is substantially equal to a width of the active layer of the second type light-emitting element.

19. The display device of claim 14, wherein the filling layer comprises an insulating material, and has a light-reflecting surface or a light-absorbing surface.

20. An electronic device comprising a display device comprising:
a substrate;
a pixel electrode above the substrate;
a first type light-emitting element above the pixel electrode, and having a contact electrode electrically connected to the pixel electrode;
a second type light-emitting element above the pixel electrode, and having a non-contact electrode;
a filling layer between the first type light-emitting element and the second type light-emitting element;
a connect electrode connecting the first type light-emitting element and the second type light-emitting element in series; and
a common electrode above the first type light-emitting element and the second type light-emitting element, and electrically connected to the second type light-emitting element.
